(19) United States
(12) Patent Application Publication
(10) Pub. No.: US 2025/0359440 A1
(43) Pub. Date: Nov. 20, 2025

(54) DISPLAY APPARATUS

(71) Applicant: Samsung Display Co., LTD., Yongin-si (KR)

(72) Inventors: Seongmin Kim, Yongin-si (KR); Minjae Kim, Yongin-si (KR); Jinkoo Chung, Yongin-si (KR)

(21) Appl. No.: 19/209,581

(22) Filed: May 15, 2025

(30) Foreign Application Priority Data
May 16, 2024 (KR) 10-2024-0064139

(51) Int. Cl. H10K 59/122; H10K 50/19; H10K 59/126; H10K 59/88

(52) U.S. Cl. CPC H10K 59/122; H10K 50/19; H10K 59/126; H10K 59/88

(57) ABSTRACT

A display apparatus includes a substrate, a first main light-emitting diode disposed on the substrate, a first sub light-emitting diode disposed on the substrate to be adjacent to the first main light-emitting diode, where the first sub light-emitting diode emits light of a same color as a color of light of the first main light-emitting diode, a bank layer defining a first main opening exposing the first main light-emitting diode and a first sub-opening exposing the first sub light-emitting diode, and a first central separator disposed on an upper surface of the bank layer, where when viewed in a direction perpendicular to the substrate, the first central separator is disposed between the first main opening and the first sub-opening.

This application claims priority to Korean Patent Application No. 10-2024-0064139, filed on May 16, 2024, and all the benefits accruing therefrom under 35 U.S.C. § 119, the content of which in its entirety is herein incorporated by reference.

### BACKGROUND

### 1. Field

One or more embodiments relate to a display apparatus.

### 2. Description of the Related Art

Recently, the usage of display apparatuses has diversified. In addition, as display apparatuses have become thinner and lighter, their range of use has been gradually extended, and as the display apparatuses are utilized in various fields, the demand for display apparatuses capable of providing high-quality images has increased. Recently, display apparatuses may be provided inside a vehicle to provide images to users sitting in the driver's or passengers' seats.

### SUMMARY

One or more embodiments include a display apparatus configured to produce high-quality images while implementing both a driver viewable mode and a driver non-viewable mode.

Additional features will be set forth in part in the description which follows and, in part, will be apparent from the description, or may be learned by practice of the presented embodiments of the disclosure.

According to one or more embodiments, a display apparatus includes a substrate, a first main light-emitting diode disposed on the substrate, a first sub light-emitting diode disposed on the substrate to be adjacent to the first main light-emitting diode, where the first sub light-emitting diode emits light of a same color as the first main light-emitting diode, a bank layer defining a first main opening exposing the first main light-emitting diode and a first sub-opening exposing the first sub light-emitting diode, and a first central separator disposed on an upper surface of the bank layer, where when viewed in a direction perpendicular to the substrate, the first central separator is arranged between the first main opening and the first sub-opening.

In an embodiment, the first central separator may be defined by a trench shape of the bank layer in which a portion of the upper surface of the bank layer is concave.

In an embodiment, the first central separator may be defined by a structure disposed on the upper surface of the bank layer, and a lateral surface of the first central separator may include a reverse tapered inclined surface.

In an embodiment, the first main light-emitting diode may include a first main pixel electrode, a first main intermediate layer on the first main pixel electrode, and a first main opposite electrode on the first main intermediate layer, the first sub light-emitting diode may include a first sub-pixel electrode, a first sub-intermediate layer on the first sub-pixel electrode, and a first sub-opposite electrode on the first sub-intermediate layer, the first main intermediate layer and the first sub-intermediate layer may be apart from each other with the first central separator therebetween, and the first main opposite electrode and the first sub-opposite electrode may be apart from each other with the first central separator therebetween.

In an embodiment, the display apparatus may further include a dummy intermediate layer disposed between the first main intermediate layer and the first sub-intermediate layer when viewed in the direction perpendicular to the substrate, and a dummy opposite electrode disposed between the first main opposite electrode and the first sub-opposite electrode when viewed in the direction perpendicular to the substrate.

In an embodiment, the dummy intermediate layer and the dummy opposite electrode may be disposed on the first central separator.

In an embodiment, the dummy intermediate layer may not be electrically connected to the first main intermediate layer and the first sub-intermediate layer, and the dummy opposite electrode may not be electrically connected to the first main opposite electrode and the first sub-intermediate layer.

In an embodiment, each of the first main intermediate layer and the first sub-intermediate layer may have a stacked structure including a lower emission layer and an upper emission layer on the lower emission layer.

In an embodiment, each of the first main intermediate layer and the first sub-intermediate layer may further include a charge generation layer disposed between the lower emission layer and the upper emission layer.

In an embodiment, the display apparatus may further include a second main light-emitting diode disposed on the substrate, where the second main light-emitting diode emits light of a color different from a color of light of the first main light-emitting diode, and a second sub light-emitting diode disposed on the substrate to be adjacent to the second main light-emitting diode, where the second sub light-emitting diode emits light of a same color as a color of light of the second main light-emitting diode, where the bank layer may further define a second main opening exposing the second main light-emitting diode, and a second sub-opening exposing the second sub light-emitting diode.

In an embodiment, the display apparatus may further include a second central separator disposed on the upper surface of the bank layer, where when viewed in the direction perpendicular to the substrate, the second central separator may be arranged between the second main opening and the second sub-opening.

In an embodiment, the first central separator and the second central separator may be integrally formed with each other as a single unitary indivisible part.

In an embodiment, the first central separator and the second central separator may be arranged to be apart from each other.

In an embodiment, the display apparatus may further include a first outer separator surrounding at least a portion of an outer portion of a first sub-pixel group including the first main light-emitting diode and the first sub light-emitting diode when viewed in the direction perpendicular to the substrate, and a second outer separator surrounding at least a portion of an outer portion of a second sub-pixel group including the second main light-emitting diode and the second sub light-emitting diode when viewed in the direction perpendicular to the substrate.

In an embodiment, when viewed in the direction perpendicular to the substrate, the first outer separator and the second outer separator may be arranged to be apart from each other between the first sub-pixel group and the second sub-pixel group.

In an embodiment, the display apparatus may further include an encapsulation layer disposed on the first main light-emitting diode and the first sub light-emitting diode, and a light-blocking layer disposed on the encapsulation layer, where, when viewed in the direction perpendicular to the substrate, the light-blocking layer may define a plurality of light-transmissive openings respectively overlapping the first main opening and the first sub-opening of the bank layer.

In an embodiment, the light-blocking layer may include a first light-blocking line and a second light-blocking line extending in directions crossing each other, where the first light-blocking line may overlap each of the first main light-emitting diode and the first sub light-emitting diode when viewed in the direction perpendicular to the substrate, and the second light-blocking line may be arranged to be adjacent to an opposite lateral surface of a lateral surface facing the first main light-emitting diode among lateral surfaces of the first sub light-emitting diode when viewed in the direction perpendicular to the substrate.

In an embodiment, the first main light-emitting diode and the first sub light-emitting diode may respectively emit light according to different electrical signals from each other.

In an embodiment, when viewed in the direction perpendicular to the substrate, an emission area of the first main light-emitting diode may be greater than an emission area of the first sub light-emitting diode.

According to one or more embodiments, a display apparatus includes a substrate, a sub-pixel group disposed on the substrate and including a main light-emitting diode and a sub light-emitting diode which emit light of a same color as each other and are disposed to be adjacent to each other, a bank layer defining a main opening exposing the main light-emitting diode, and a sub opening exposing the sub light-emitting diode, and a separator disposed on an upper surface of the bank layer, where, the separator may include an outer separator surrounding at least a portion of an outer portion of the sub-pixel group when viewed in a direction perpendicular to the substrate, and a central separator disposed between the main light-emitting diode and the sub light-emitting diode when viewed in the direction perpendicular to the substrate.

In an embodiment, the separator may be defined by a trench shape of the bank layer in which a portion of the upper surface of the bank layer is concave.

In an embodiment, the separator may be defined by a structure disposed on the upper surface of the bank layer, and a lateral surface of the separator may include a reverse tapered inclined surface.

In an embodiment, the main light-emitting diode may include a main pixel electrode, a main intermediate layer on the main pixel electrode, and a main opposite electrode on the main intermediate layer, the sub light-emitting diode may include a sub-pixel electrode, a sub-intermediate layer on the sub-pixel electrode, and a sub-opposite electrode on the sub-intermediate layer, the main intermediate layer and the sub-intermediate layer may be apart from each other with the central separator therebetween, and the main opposite electrode and the sub-opposite electrode may be apart from each other with the central separator therebetween.

In an embodiment, the main light-emitting diode and the sub light-emitting diode may respectively emit light according to different electrical signals from each other.

### BRIEF DESCRIPTION OF THE DRAWINGS

The above and other features of certain embodiments of the disclosure will be more apparent from the following description taken in conjunction with the accompanying drawings, in which:

FIG. 1 is a schematic perspective view of a display apparatus according to an embodiment;

FIG. 2 is a schematic cross-sectional view of the display apparatus of FIG. 1, taken along line A-A′ of FIG. 1;

FIG. 3 is an equivalent circuit diagram of a sub-pixel of a display apparatus according to an embodiment;

FIGS. 4 and 5 are enlarged plan views of a portion of a display apparatus according to an embodiment;

FIG. 6 is a schematic cross-sectional view of the display apparatus of FIG. 5, taken along line C-C′ of FIG. 5;

FIG. 7 is a schematic enlarged cross-sectional view of a region D of the display apparatus of FIG. 6;

FIG. 8 is a schematic cross-sectional view of a display apparatus according to another embodiment;

FIG. 9 is an enlarged plan view of a display apparatus according to another embodiment;

FIG. 10 is an enlarged plan view of a display apparatus according to another embodiment;

FIG. 11 is an enlarged plan view of a display apparatus according to another embodiment; and

FIG. 12 is a schematic view of a vehicle including a display apparatus according to an embodiment.

FIG. 13 is a block diagram of an electronic apparatus according to an embodiment.

FIG. 14 is a schematic diagrams of electronic apparatuses according to various embodiments.

### DETAILED DESCRIPTION

The invention now will be described more fully hereinafter with reference to the accompanying drawings, in which various embodiments are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art. Like reference numerals refer to like elements throughout.

As the disclosure allows for various changes and numerous embodiments, certain embodiments will be illustrated in the drawings and described in the written description. Effects and features of the disclosure, and methods for achieving them will be clarified with reference to embodiments described below in detail with reference to the drawings. However, the disclosure is not limited to the following embodiments and may be embodied in various forms.

It will be understood that when an element is referred to as being “on” another element, it can be directly on the other element or intervening elements may be present therebetween. In contrast, when an element is referred to as being “directly on” another element, there are no intervening elements present.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. Thus, reference to “an” element in a claim followed by reference to “the” element is inclusive of one element and a plurality of the elements. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. Throughout the disclosure, the expression “at least one of a, b or c” or “at least one selected from a, b or c” indicates only a, only b, only c, both a and b, both a and c, both b and c, all of a, b, and c, or variations thereof.

It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

It will be further understood that, when a layer, region, or element is referred to as being “on” another layer, region, or element, it can be directly or indirectly on the other layer, region, or element. That is, for example, intervening layers, regions, or elements may be present therebetween.

Sizes of elements in the drawings may be exaggerated or reduced for convenience of explanation. For example, the size and thickness of each element shown in the drawings are arbitrarily represented for convenience of description, and thus, the disclosure is not necessarily limited thereto.

In the case where a certain embodiment may be implemented differently, a specific process order may be performed in the order different from the described order. For example, two processes successively described may be simultaneously performed substantially and performed in the opposite order.

It will be understood that when a layer, region, or element is referred to as being “connected” to another layer, region, or element, it may be “directly connected” to the other layer, region, or element or may be “indirectly connected” to the other layer, region, or element with another layer, region, or element located therebetween. For example, it will be understood that when a layer, region, or element is referred to as being “electrically connected” to another layer, region, or element, it may be “directly electrically connected” to the other layer, region, or element or may be “indirectly electrically connected” to the other layer, region, or element with another layer, region, or element disposed therebetween.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±30%, 20%, 10% or 5% of the stated value.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

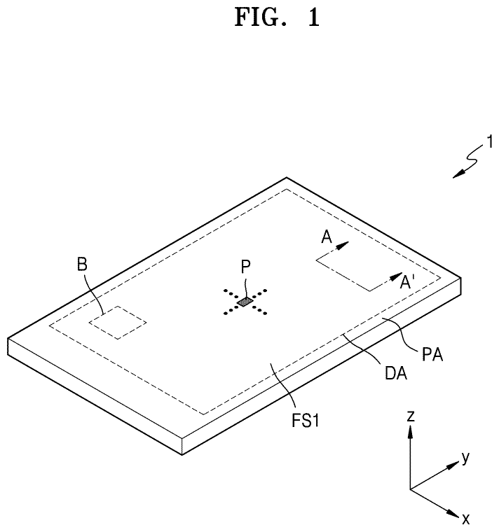

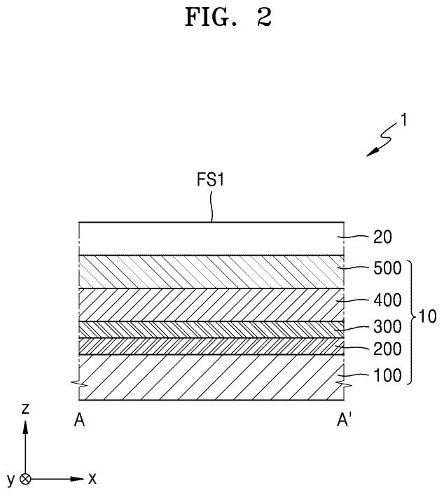

FIG. 1 is a schematic perspective view of a display apparatus 1 according to an embodiment. FIG. 2 is a schematic cross-sectional view of the display apparatus 1 of FIG. 1, taken along line A-A′ of FIG. 1.

Referring to FIG. 1, the display apparatus 1 according to an embodiment may include a display area DA and a peripheral area PA. The peripheral area PA may be arranged outside the display area DA to surround the display area DA. Various wirings and a driving circuit part that generate or transfer electrical signals to be applied to the display area DA may be arranged in the peripheral area PA. The display apparatus 1 may be configured to display images by using light emitted from a plurality of sub-pixels P arranged in the display area DA.

Hereinafter, for convenience of description, embodiments where the display apparatus is an organic light-emitting display apparatus will be described as an example, but the display apparatus according to an embodiment is not limited thereto. The display apparatus 1 may be an organic light-emitting display, an inorganic light-emitting display, or a quantum-dot light-emitting display.

The display apparatus 1 may be implemented as any of various kinds of electronic apparatuses. In an embodiment, the display apparatus 1 may be a display apparatus for a vehicle, but the display apparatus according to an embodiment is not limited thereto.

As shown in FIG. 2, an embodiment of the display apparatus 1 may include a display panel 10 and a cover window 20. The display panel 10 may include a substrate 100, a pixel circuit layer 200, a display element layer 300, an encapsulation layer 400, and a light-blocking layer 500 sequentially stacked in a third direction (e.g., a z direction or a thickness direction).

The substrate 100 may include glass and/or polymer resin. In an embodiment, for example, the substrate 100 may include a glass material including SiOₓ as a primary component, or a polymer resin including at least one selected from polyethersulfone, polyacrylate, polyetherimide, polyethylene naphthalate, polyethylene terephthalate, polyphenylene sulfide, polyimide, polycarbonate, cellulose tri acetate, and cellulose acetate propionate.

The pixel circuit layer 200 may be disposed on the substrate 100. The pixel circuit layer 200 may include sub-pixel circuits, wirings, and insulating layers arranged in the display area DA. Some of the wirings and the insulating layers of the pixel circuit layer 200 may extend to the peripheral area PA.

The display element layer 300 may be disposed on the pixel circuit layer 200. The display element layer 300 may include display elements arranged in the display area DA. Each display element may be electrically connected to a corresponding sub-pixel circuit to form one sub-pixel.

The encapsulation layer 400 may be disposed on the display element layer 300. The encapsulation layer 400 may encapsulate display elements located in the display element layer 300. In an embodiment, the encapsulation layer 400 may include at least one inorganic encapsulation layer and at least one organic encapsulation layer. The at least one inorganic encapsulation layer may include at least one inorganic material selected from aluminum oxide (Al₂O₃), titanium oxide (TiO₂), tantalum oxide (Ta₂O₅), zinc oxide (ZnO), silicon oxide (SiOₓ), silicon nitride (SiNₓ), and silicon oxynitride (SiON). The at least one organic encapsulation layer may include a polymer-based material. The polymer-based material may at least one selected from include an acryl-based resin, an epoxy-based resin, polyimide, and polyethylene. In an embodiment, for example, the at least one organic encapsulation layer may include acrylate.

The light-blocking layer 500 may be disposed on the encapsulation layer 400. The light-blocking layer 500 may partially absorb light emitted by the display element layer 300 to limit a viewing angle of the display apparatus 1. In an embodiment, for example, the light-blocking layer 500 may selectively transmit only a portion of light and block the rest of light depending on an angle formed by light emitted by the display element layer and the third direction (the z direction) perpendicular to a front surface FS1 of the display apparatus 1. The light-blocking layer 500 may be arranged in the display area DA. The light-blocking layer 500 may include a transmissive area to transmit light emitted by the display element layer 300.

The cover window 20 may be disposed on the display panel 10. In an embodiment, the cover window 20 may be coupled to an element therebelow, for example, the light-blocking layer 500 using the optically clear adhesive. The cover window 20 may be configured to protect the display panel 10. The cover window 20 may include at least one selected from glass, sapphire, and plastic. The cover window 20 may be, for example, ultra-thin glass or colorless polyimide.

Although not shown in FIG. 2, a touch sensor layer may be further disposed between the encapsulation layer 400 and the light-blocking layer 500, or between the light-blocking layer 500 and the cover window 20. The touch sensor layer is a layer configured to sense a user's touch input and may sense a user's touch input using at least one of various touch methods such as a resistance layer method, a capacitance method, and the like.

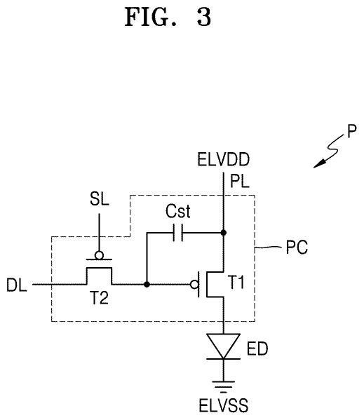

FIG. 3 is an equivalent circuit diagram of a sub-pixel of a display apparatus according to an embodiment.

Referring to FIG. 3, an embodiment of a sub-pixel P may include a light-emitting diode ED as a display element, and a sub-pixel circuit PC connected to the light-emitting diode ED. The sub-pixel circuit PC may include a first thin-film transistor T1, a second thin-film transistor T2, and a storage capacitor Cst. The light-emitting diode ED may be configured to emit, for example, red, green, or blue light, or emit red, green, blue, or white light.

The second thin-film transistor T2 is a switching thin-film transistor, may be connected to a scan line SL and a data line DL, and configured to transfer a data voltage to the first thin-film transistor T1 based on a switching voltage, the data voltage being input from the data line DL, and the switching voltage being input from the scan line SL. The storage capacitor Cst may be connected to the second thin-film transistor T2 and a driving voltage line PL and configured to store a voltage corresponding to a difference between a data voltage transferred from the second thin-film transistor T2 and a first power voltage ELVDD supplied to the driving voltage line PL.

The first thin-film transistor T1 is a driving thin-film transistor, may be connected to the driving voltage line PL and the storage capacitor Cst, and configured to control a driving current in response to the voltage stored in the storage capacitor Cst, the driving current flowing through the light-emitting diode ED. The light-emitting diode ED may be configured to emit light having a preset brightness corresponding to the driving current. An opposite electrode (e.g., a cathode) of the light-emitting diode ED may be configured to receive a second power voltage ELVSS.

Although an embodiment where the sub-pixel circuit PC includes two transistors and one capacitor is shown in FIG. 3, the disclosure is not limited thereto. The number of thin-film transistors and the number of capacitors may be variously changed according to the design of the sub-pixel circuit PC.

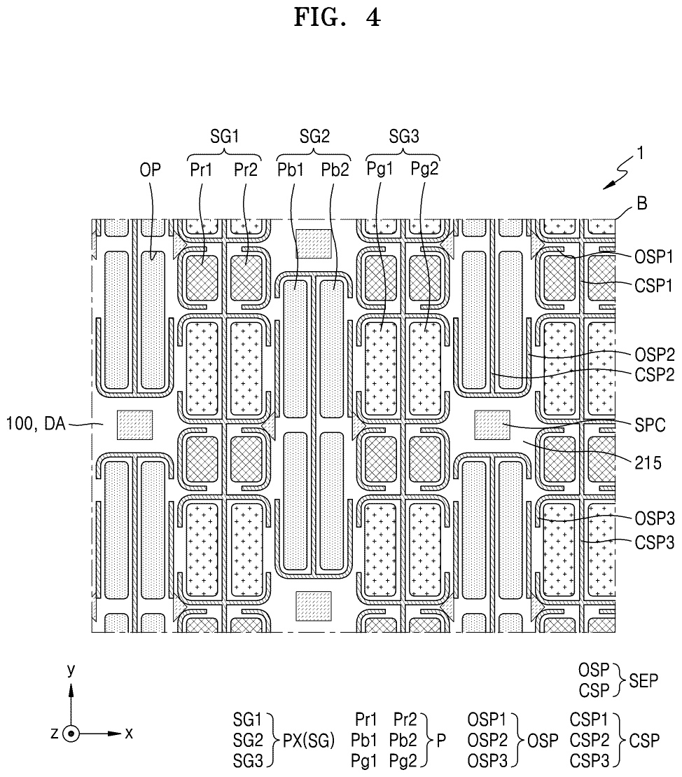

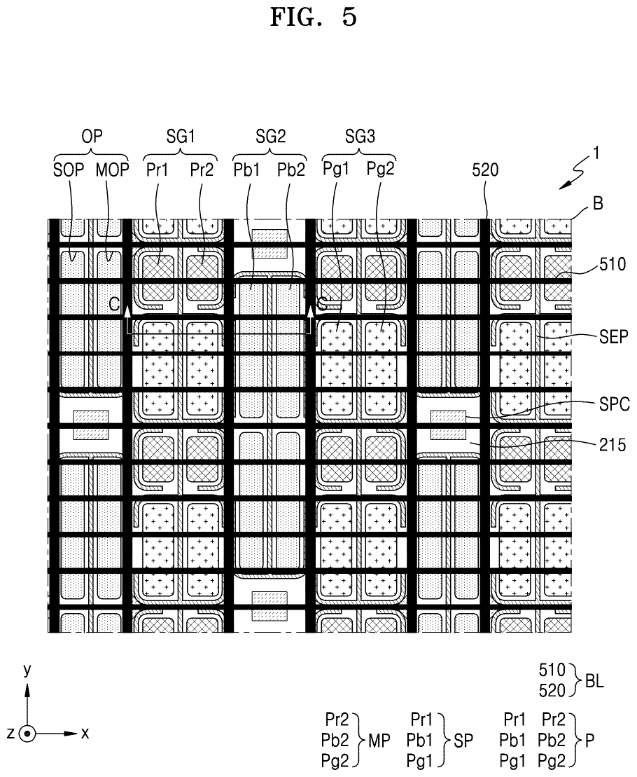

FIGS. 4 and 5 are enlarged plan views of a portion of a display apparatus according to an embodiment. Specifically, FIGS. 4 and 5 are enlarged plan views of a region B of the display apparatus 1 of FIG. 1.

Referring to FIG. 4, an embodiment of the display apparatus 1 may include the substrate 100. In an embodiment, as described above with reference to FIG. 1, the display apparatus 1 may include the display area DA and the peripheral area PA outside the display area DA.

A plurality of pixels PX may be arranged in the display area DA. In an embodiment, for example, the pixels PX may form an array in a first direction (an x direction) and a second direction (a y direction) in the display area DA. Each pixel PX may include sub-pixels P configured to emit light of one of red, green, blue, and white. In the disclosure, the pixel PX may be defined or denoted by a plurality of sub-pixel groups SG. In an embodiment, the pixel PX may include a first sub-pixel group SG1 configured to emit red light, a second sub-pixel group SG2 configured to emit blue light, and a third sub-pixel group SG3 configured to emit green light. In an embodiment, for example, a pixel PX may include two red sub-pixels Pr1 and Pr2, two green sub-pixels Pg1 and Pg2, and two blue sub-pixels Pb1 and Pb2. In an embodiment, a pixel PX may further include two white sub-pixels.

The first sub-pixel group SG1, the second sub-pixel group SG2, and the third sub-pixel group SG3 may be configured to respectively emit light of different colors. In an embodiment, for example, the first sub-pixel group SG1 may be configured to emit red light in a wavelength band of about 580 nanometers (nm) to about 780 nm, the third sub-pixel group SG3 may be configured to emit green light in a wavelength band of about 495 nm to about 580 nm, and the second sub-pixel group SG2 may be configured to emit blue light in a wavelength band of about 380 nm to about 495 nm. Each of the plurality of sub-pixels P may include the light-emitting diode ED (see FIG. 3), and the light-emitting diode ED may include a pixel electrode, an opposite electrode, and an intermediate layer therebetween.

In an embodiment, a bank layer 215 may be disposed on the substrate 100. The bank layer 215 may be disposed on the pixel electrodes of the plurality of sub-pixels P. That is, the bank layer 215 may be provided with a plurality of openings OP exposing the central portions of the plurality of pixel electrodes. Although not shown in FIG. 4, emission layers configured to emit light may be disposed in the opening OP of the bank layer 215, and the opposite electrode may be disposed on the emission layers. The plurality of sub-pixels P shown in FIG. 4 represent emission areas of the respective light-emitting diodes.

The sub-pixels P belonging to each sub-pixel group may be configured to emit light based on different electrical signals from each other. In an embodiment, the first red sub-pixel Pr1 and the second red sub-pixel Pr2 in the first sub-pixel group SG1 may be driven independently of each other, the first blue sub-pixel Pb1 and the second blue sub-pixel Pb2 in the second sub-pixel group SG2 may be driven independently of each other, and the first green sub-pixel Pg1 and the second green sub-pixel Pg2 in the third sub-pixel group SG3 may be driven independently of each other.

Sub-pixels P in each sub-pixel group may be apart from each other in the first direction (the x direction). In an embodiment, for example, the first red sub-pixel Pr1 and the second red sub-pixel Pr2 in the first sub-pixel group SG1 may be apart from each other in the first direction (the x direction), the first blue sub-pixel Pb1 and the second blue sub-pixel Pb2 in the second sub-pixel group SG2 may be apart from each other in the first direction (the x direction), and the first green sub-pixel Pg1 and the second green sub-pixel Pg2 in the third sub-pixel group SG3 may be apart from each other in the first direction (the x direction).

The first sub-pixel group SG1 and the second sub-pixel group SG2 may be apart from each other in the first direction (the x direction). The first sub-pixel group SG1 and the third sub-pixel group SG3 may be apart from each other in the second direction (the y direction). The first sub-pixel group SG1 and the third sub-pixel group SG3 may be alternately arranged in the second direction (the y direction). The third sub-pixel group SG3 and the second sub-pixel group SG2 may be apart from each other in the first direction (the x direction). That is, the first red sub-pixel Pr1 and the first green sub-pixel Pg1 may be apart from each other in the second direction (the y direction), and the second red sub-pixel Pr2 and the second green sub-pixel Pg2 may be apart from each other in the second direction (the y direction). The first blue sub-pixel Pb1 may be apart from the second red sub-pixel Pr2 and the second green sub-pixel Pg2 in the first direction (the x direction).

Referring to FIG. 5, the display apparatus 1 may further include a plurality of light-blocking lines BL included in (or defined by portions of) the light-blocking layer 500 (see FIG. 2). The plurality of light-blocking lines BL may be configured to reflect or absorb light emitted from the plurality of sub-pixels P. The light-blocking line BL may include a plurality of first light-blocking lines 510 extending in the first direction (the x direction), and a plurality of second light-blocking lines 520 extending in the second direction (the y direction).

The plurality of first light-blocking lines 510 may be apart from each other at regular intervals, and the plurality of second light-blocking lines 520 may be apart from each other at regular intervals. In an embodiment, a distance between the plurality of second light-blocking lines 520 may be greater than a distance between the plurality of first light-blocking lines 510.

In an embodiment, the plurality of first light-blocking lines 510 may overlap each of the first red sub-pixel Pr1 and the second red sub-pixel Pr2. The plurality of first light-blocking lines 510 may overlap each of the first green sub-pixel Pg1 and the second green sub-pixel Pg2. The plurality of first light-blocking lines 510 may overlap each of the first blue sub-pixel Pb1 and the second blue sub-pixel Pb2. The plurality of second light-blocking lines 520 may be arranged to be adjacent to one of the sub-pixels P in the sub-pixel group. In an embodiment, for example, the plurality of second light-blocking lines 520 may be arranged to be adjacent to an opposite lateral side of a lateral side facing the second red sub-pixel Pr2 among the lateral sides of the first red sub-pixel Pr1. The plurality of second light-blocking lines 520 may be arranged to be adjacent to an opposite lateral side of a lateral side facing the second green sub-pixel Pg2 among the lateral sides of the first green sub-pixel Pg1. The plurality of second light-blocking lines 520 may be arranged to be adjacent to an opposite lateral side of a lateral side facing the second blue sub-pixel Pb2 among the lateral sides of the first blue sub-pixel Pb1.

The plurality of light-blocking lines BL may be configured to limit a specific direction component of light emitted from the plurality of sub-pixels P. In an embodiment, for example, when a second direction (y direction) component of light emitted from the plurality of sub-pixels P exceeds a preset value and has an emission angle greater than a cut-off angle, the emitted light may be blocked by the plurality of first light-blocking lines 510. In such an embodiment, when a first direction (x direction) component of light emitted from the plurality of sub-pixels P exceeds a preset value and has an emission angle greater than a cut-off angle, the emitted light may be blocked by the plurality of second light-blocking lines 520.

In an embodiment where the display apparatus 1 is used as a display apparatus for a vehicle using the characteristics of the light-blocking lines BL and the configuration structure of the sub-pixels P, the display apparatus 1 may be configured to implement two modes including a driver viewable mode and a driver non-viewable mode.

In an embodiment where the display apparatus 1 is used as a display apparatus for a vehicle, light emitted from the first red sub-pixel Pr1, the first blue sub-pixel Pb1, and the first green sub-pixel Pg1 and directed toward a driver, may be reflected or absorbed by the plurality of second light-blocking lines 520 and may not visible to a user sitting in the driver's seat. In such an embodiment, because light emitted from the second red sub-pixel Pr2, the second blue sub-pixel Pb2, and the second green sub-pixel Pg2 and directed toward a driver, does not pass through the plurality of second light-blocking lines 520 and may be visible to a user sitting in the driver's seat. In such an embodiment, the first red sub-pixel Pr1, the first blue sub-pixel Pb1, and the first green sub-pixel Pg1 may have a viewing angle limited on the driver's side due to the plurality of second light-blocking lines 520, and the second red sub-pixel Pr2, the second blue sub-pixel Pb2, and the second green sub-pixel Pg2 may not have a viewing angle limited on the driver's side.

In such an embodiment having the above structure, when only the second red sub-pixel Pr2, the second blue sub-pixel Pb2, and the second green sub-pixel Pg2 emit light, because the light emitted from the second red sub-pixel Pr2, the second blue sub-pixel Pb2, and the second green sub-pixel Pg2 may be visible to both a driver seat user and a passenger seat user, the display apparatus 1 may operate in a driver viewable mode. In such an embodiment, when only the first red sub-pixel Pr1, the first blue sub-pixel Pb1, and the first green sub-pixel Pg1 emit light, because light emitted from the first red sub-pixel Pr1, the first blue sub-pixel Pb1, and the first green sub-pixel Pg1 may be visible to only a passenger seat user and may not be visible to a driver seat user, the display apparatus 1 may operate in a driver non-viewable mode.

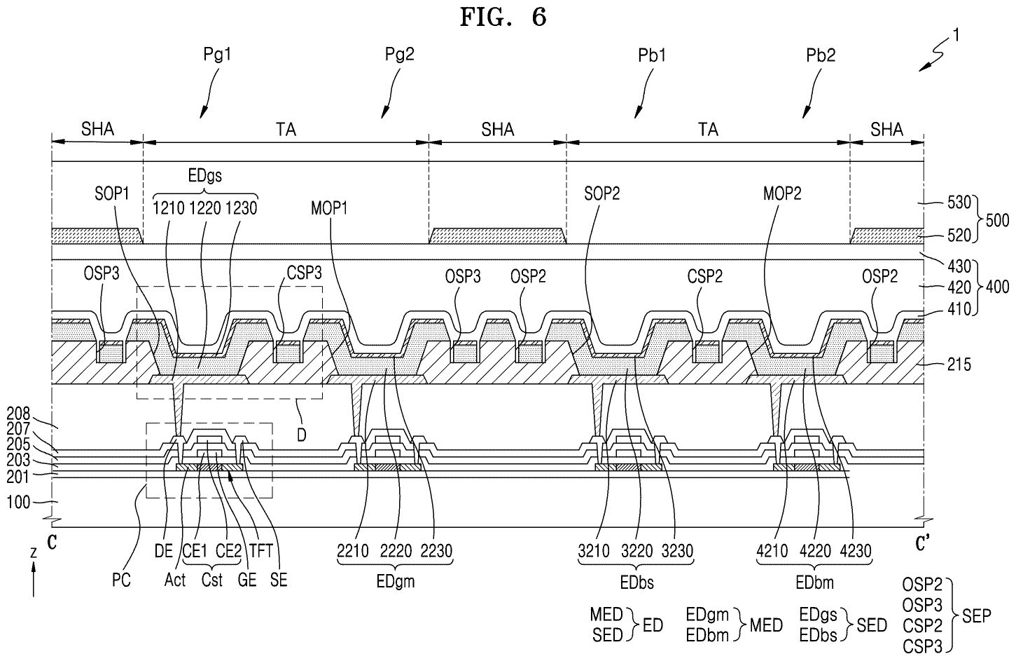

In the disclosure, the second red sub-pixel Pr2, the second blue sub-pixel Pb2, and the second green sub-pixel Pg2 may be referred to as main sub-pixels MP, and a light-emitting diode included in each of the second red sub-pixel Pr2, the second blue sub-pixel Pb2, and the second green sub-pixel Pg2 may be referred to as a main light-emitting diode MED (see FIG. 6). Likewise, the first red sub-pixel Pr1, the first blue sub-pixel Pb1, and the first green sub-pixel Pg1 may be referred to as sub sub-pixels SP, and a light-emitting diode included in each of the first red sub-pixel Pr1, the first blue sub-pixel Pb1, and the first green sub-pixel Pg1 may be referred to as a sub light-emitting diode SED (see FIG. 6). In addition, an opening OP of the bank layer 215 in which the emission area of each of the second red sub-pixel Pr2, the second blue sub-pixel Pb2, and the second green sub-pixel Pg2 is defined may be referred to as main opening MOP, and an opening OP of the bank layer 215 in which the emission area of each of the first red sub-pixel Pr1, the first blue sub-pixel Pb1, and the first green sub-pixel Pg1 is defined may be referred to as a sub-opening SOP.

That is, the main light-emitting diode MED (see FIG. 6) of the main sub-pixel MP may emit light during the driver viewable mode that may be implemented while a vehicle is not driven. The sub light-emitting diode SED of the sub sub-pixel SP may emit light during the driver non-viewable mode that may be implemented while a vehicle is driven.

Referring back to FIG. 4, the display apparatus 1 may further include a separator SEP and a spacer SPC. The separator SEP and the spacer SPC may be disposed on the upper surface of the bank layer 215. In an embodiment, the separator SEP may be defined by a trench shape of the bank layer 215 in which a portion of the upper surface of the bank layer 215 is concave. The spacer SPC may be disposed on an upper surface of the bank layer 215 and may be a structure having a reverse tapered inclined surface as a lateral surface thereof. As shown in FIG. 4, the spacer SPC may be arranged in an empty space in which the plurality of sub-pixels P are not arranged.

As will be described below in detail with reference to FIG. 6, the separator SEP is a trench formed in the upper surface of the bank layer 215 and may disconnect the intermediate layer and the opposite electrode of each of the plurality of light-emitting diodes. Accordingly, the separator SEP may be configured to effectively prevent a leakage current between sub-pixels P arranged to be adjacent to each other and effectively prevent color mixing of the plurality of sub-pixels P.

In such an embodiment, the separator SEP may surround at least a portion of the outer portion of each of the plurality of sub-pixels P. In an embodiment, the separator SEP may include an outer separator OSP and a central separator CSP.

In an embodiment, the outer separator OSP may be arranged to surround at least a portion of the outer portion of each sub-pixel group when viewed in a direction (a z direction) perpendicular to the substrate 100. The outer separator OSP may include a first outer separator OSP1 surrounding at least a portion of the outer portion of the first sub-pixel group SG1, a second outer separator OSP2 surrounding at least a portion of the outer portion of the second sub-pixel group SG2, and a third outer separator OSP3 surrounding at least a portion of the outer portion of the third sub-pixel group SG3.

In an embodiment, for example, when viewed in the third direction (the z direction), the first outer separator OSP1 may have a shape surrounding a portion of the upper side, a portion of the lower side, and the lateral side of the first sub-pixel group SG1. In a plan view, the second outer separator OSP2 may have a shape surrounding a portion of the lateral side, the upper side, and the lower side of the second sub-pixel group SG2. In a plan view, the third outer separator OSP3 may have a shape surrounding a portion of the lateral side, the upper side, and the lower side of the third sub-pixel group SG3.

Accordingly, two separators SEP may be arranged between sub-pixel groups arranged to be adjacent to each other. in an embodiment, the first outer separator OSP1 and the second outer separator OSP2 may be arranged in the first direction (the x direction) in a region between the first sub-pixel group SG1 and the second sub-pixel group SG2. The first outer separator OSP1 and the third outer separator OSP3 may be arranged in the second direction (the y direction) in a region between the first sub-pixel group SG1 and the third sub-pixel group SG3. The second outer separator OSP2 and the third outer separator OSP3 may be arranged in the first direction (the x direction) in a region between the second sub-pixel group SG2 and the third sub-pixel group SG3.

Because two separators SEP are arranged between sub-pixel groups arranged to be adjacent to each other, the display apparatus 1 according to an embodiment may be configured to efficiently prevent a leakage current and color mixing defects between the sub-pixel groups configured to emit light of different colors.

In an embodiment, when viewed in a direction (the z direction) perpendicular to the substrate 100, the central separator CSP may be arranged between sub-pixels P configured to emit light of a same color and arranged to be adjacent to each other. In an embodiment, the central separator CSP may be arranged between sub-pixels P in a same sub-pixel group. The central separator CSP may be arranged between the main sub-pixel MP and the sub sub-pixel SP. That is, the central separator CSP may be arranged between the main opening MOP and the sub-opening SOP. In an embodiment, the central separator CSP may include a first central separator CSP1 arranged between the first red sub-pixel Pr1 and the second red sub-pixel Pr2, a second central separator CSP2 arranged between the first blue sub-pixel Pb1 and the second blue sub-pixel Pb2, and a third central separator CSP3 arranged between the first green sub-pixel Pg1 and the second green sub-pixel Pg2.

The central separator CSP may extend in the second direction (the y direction). The central separator CSP may be arranged between the main sub-pixel MP and the sub sub-pixel SP and arranged to be parallel to the lateral sides facing each other, of each of the main sub-pixel MP and the sub sub-pixel SP.

In an embodiment, some of the plurality of central separators CSP may be connected to each other to be integrally formed as a single unitary indivisible part. In an embodiment, for example, as shown in FIG. 4, where the first sub-pixel group SG1 and the third sub-pixel group SG3 are alternately arranged in the second direction (the y direction), the first central separator CSP1 and the third central separator CSP3 may be connected to each other to be integrally formed as a single unitary indivisible part. In an embodiment, where two second sub-pixel groups SG2 are arranged side-by-side in the second direction (the y direction) without the spacer SPC therebetween, the second central separator CSP2 may extend to overlap the two second sub-pixel groups SG2.

In an embodiment, as described above, the main sub-pixel MP and the sub sub-pixel SP may be independently driven to implement both the driver viewable mode and the driver non-viewable mode. In the display apparatus 1 according to an embodiment, because the separator SEP is arranged even between the main sub-pixel MP and the sub sub-pixel SP arranged to be adjacent to each other and configured to emit light of a same color, a leakage current may be effectively prevented even between the sub-pixels P configured to emit light of the same color.

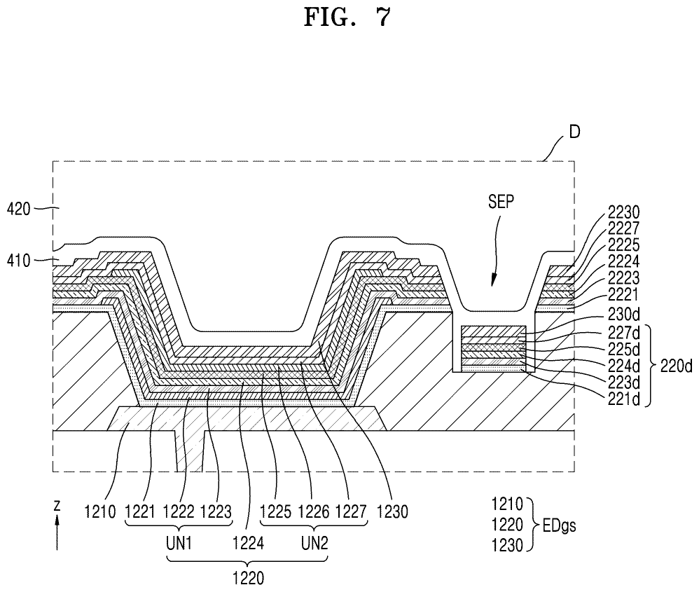

FIG. 6 is a schematic cross-sectional view of the display apparatus 1 of FIG. 5, taken along line C-C′ of FIG. 5. FIG. 7 is a schematic enlarged cross-sectional view of a region D of the display apparatus 1 of FIG. 6.

Referring to FIG. 6, an embodiment of the display apparatus 1 may include the substrate 100. The substrate 100 may include at least one selected from various flexible or bendable materials. In an embodiment, for example, the substrate 100 may include glass, metal, or polymer resin. In such an embodiment, the substrate 100 may include polymer resin such as polyethersulphone, polyacrylate, polyetherimide, polyethylene naphthalate, polyethylene terephthalate, polyphenylene sulfide, polyarylate, polyimide, polycarbonate, or cellulose acetate propionate. The substrate 100 may have a multi-layered structure including two layers each including the polymer resin, and a barrier layer including an inorganic material (such as silicon oxide, silicon nitride, and silicon oxynitride) therebetween. However, various modifications may be made.

The plurality of sub-pixels P (see FIG. 5) each including the sub-pixel circuit PC and the display element may be disposed on the substrate 100. In an embodiment, as shown in FIG. 4, the plurality of sub-pixels P (see FIG. 5) include the light-emitting diode ED as the display element. The light-emitting diode ED may include the main light-emitting diode MED and the sub light-emitting diode SED. In an embodiment, for example, the light-emitting diode ED may include a first main light-emitting diode EDgm, a first sub light-emitting diode EDgs, a second main light-emitting diode EDbm, and a second sub light-emitting diode EDbs. That is, the first green sub-pixel Pg1 may include the first sub light-emitting diode EDgs as the sub sub-pixel SP (see FIG. 5), and the second green sub-pixel Pg2 may include the first main light-emitting diode EDgm as the main sub-pixel MP (see FIG. 5). In such an embodiment, the first blue sub-pixel Pb1 may include the second sub light-emitting diode EDbs as the sub sub-pixel SP (see FIG. 5), and the second blue sub-pixel Pb2 may include the second main light-emitting diode EDbm as the main sub-pixel MP (see FIG. 5).

The sub-pixel circuit PC may be disposed on the substrate 100. Because the structure of the sub-pixel circuit PC of each sub-pixel P (see FIG. 5) is the same as each other, one sub-pixel circuit PC will hereinafter be mainly described. The sub-pixel circuit PC includes a plurality of thin-film transistors TFT and a storage capacitor Cst. For convenience of illustration, FIG. 6 shows one thin-film transistor TFT. The thin-film transistor TFT may correspond to the driving thin-film transistor T1 (see FIG. 3) described above.

A buffer layer 201 may be disposed between the thin-film transistor TFT and the substrate 100, and the buffer layer 201 includes an inorganic material such as silicon oxide, silicon nitride, and/or silicon oxynitride. The buffer layer 201 may increase flatness of the upper surface of the substrate 100, or effectively prevent or substantially reduce impurities from the substrate 100 and the like penetrating into a semiconductor layer Act of the thin-film transistor TFT.

In an embodiment, as shown in FIG. 6, the thin-film transistor TFT may include the semiconductor layer Act including amorphous silicon, polycrystalline silicon, an organic semiconductor material, or an oxide semiconductor material. The thin-film transistor TFT may include a gate electrode GE, a source electrode SE, and/or a drain electrode DE. The gate electrode GE may include at least one selected from various conductive materials and have various layered structures, and include, for example, a Mo layer and an Al layer. Alternatively, the gate electrode GE may include a TiNₓ layer, an Al layer, and/or a Ti layer. The source electrode SE and the drain electrode DE may also include at least one selected from various conductive materials and various layered structures, and may include, for example, a Ti layer, an Al layer, and/or a Cu layer.

To secure insulation between the semiconductor layer Act and the gate electrode GE, a gate insulating layer 203 may be disposed between the semiconductor layer Act and the gate electrode GE, and the gate insulating layer 203 includes an inorganic material such as silicon oxide, silicon nitride, and/or silicon oxynitride. Although FIG. 6 shows an embodiment where the gate insulating layer 203 has a shape corresponding to the entire surface of the substrate 100, and has a structure in which contact holes are formed in preset portions, the disclosure is not limited thereto. In another embodiment, for example, the gate insulating layer 203 may be patterned in a same shape as the gate electrode GE.

In an embodiment, a first interlayer insulating layer 205 may be disposed on the gate electrode GE, and the first interlayer insulating layer 205 includes an inorganic material such as silicon oxide, silicon nitride, and/or silicon oxynitride. The first interlayer insulating layer 205 may have a single layer structure or a multi-layered structure, each layer therein including at least one selected from the above materials. The insulating layer including the inorganic material may be formed by chemical vapor deposition (CVD) or atomic layer deposition (ALD). This is also applicable to embodiments below and modifications thereof.

The storage capacitor Cst may include a first electrode CE1 and a second electrode CE2 overlapping each other with the first interlayer insulating layer 205 therebetween. The storage capacitor Cst may overlap the thin-film transistor TFT. Although FIG. 6 shows an embodiment where the gate electrode GE of the thin-film transistor TFT serves as the first electrode CE1 of the storage capacitor Cst, the disclosure is not limited thereto. In another embodiment, for example, the storage capacitor Cst may not overlap the thin-film transistor TFT. The second electrode CE2 of the storage capacitor Cst may include a conductive material including molybdenum (Mo), aluminum (Al), copper (Cu), titanium (Ti), and the like, and have a single layer structure or a multi-layered structure, each layer therein including at least one selected from the above materials.

A second interlayer insulating layer 207 may be disposed on the second electrode CE2 of the storage capacitor Cst, and the second interlayer insulating layer 207 includes an inorganic material such as silicon oxide, silicon nitride, and/or silicon oxynitride. The second interlayer insulating layer 207 may have a single layer structure or a multi-layered structure, each layer therein including at least one selected from the above materials.

The source electrode SE and the drain electrode DE may be disposed on the second interlayer insulating layer 207. The data line DL may be disposed in (or directly on) a same layer as the source electrode SE and the drain electrode DE and may include a same material as a material of the source electrode SE and the drain electrode DE. The source electrode SE, the drain electrode DE, and the data line DL may each include a material having high conductivity. The source electrode SE and the drain electrode DE may each include a conductive material including molybdenum (Mo), aluminum (Al), copper (Cu), or titanium (Ti) and have a single layer structure or a multi-layered structure, each layer therein including at least one selected from the above materials. In an embodiment, for example, the source electrode SE, the drain electrode DE, and the data line DL may each have a multi-layered structure of Ti/Al/Ti.

However, the disclosure is not limited thereto. In another embodiment, for example, the thin-film transistor TFT may include only one of the source electrode SE and the drain electrode DE, or may not include both. In another embodiment, for example, one thin-film transistor TFT may not include the drain electrode DE, another thin-film transistor TFT connected to the one thin-film transistor TFT may not include the source electrode SE, and the semiconductor layers Act of the two thin-film transistors TFT may be connected to each other. This connection structure may have a same effect as an effect in which one thin-film transistor TFT includes the source electrode SE, another thin-film transistor TFT has the drain electrode DE, and the source electrode SE of the one thin-film transistor TFT is connected to the drain electrode DE of the other thin-film transistor TFT.

In an embodiment, as shown in FIG. 6, a planarization layer 208 may be disposed to cover the thin-film transistor TFT and the storage capacitor Cst. The planarization layer 208 may include an organic insulating material. In an embodiment, for example, the planarization layer 208 may include benzocyclobutene (BCB), polyimide, hexamethyldisiloxane (HMDSO), polymethylmethacrylate (PMMA), polystyrene, polymer derivatives having a phenol-based group, an acryl-based polymer, an imide-based polymer, an aryl ether-based polymer, an amide-based polymer, a fluorine-based polymer, a p-xylene-based polymer, a vinyl alcohol-based polymer, or a mixture thereof. Although not shown in FIG. 6, a third interlayer insulating layer (not shown) may be further disposed under the planarization layer 208. The third interlayer insulating layer may include an inorganic insulating material such as silicon oxide, silicon nitride, or silicon oxynitride.

The first sub light-emitting diode EDgs, the first main light-emitting diode EDgm, the second sub light-emitting diode EDbs, and the second main light-emitting diode EDbm may be apart from each other on the planarization layer 208. The first sub light-emitting diode EDgs and the first main light-emitting diode EDgm may be configured to emit light of the same color, and the second sub light-emitting diode EDbs, and the second main light-emitting diode EDbm may be configured to emit light of a same color. However, the first main light-emitting diode EDgm and the second main light-emitting diode EDbm may be configured to emit light of different colors from each other. In an embodiment, for example, the first sub light-emitting diode EDgs and the first main light-emitting diode EDgm may be configured to emit green light, and the second sub light-emitting diode EDbs, and the second main light-emitting diode EDbm may be configured to emit blue light.

The first sub light-emitting diode EDgs may include a first sub-pixel electrode 1210, a first sub-intermediate layer 1220, and a first sub-opposite electrode 1230. The first main light-emitting diode EDgm may include a first main pixel electrode 2210, a first main intermediate layer 2220, and a first main opposite electrode 2230. The second sub light-emitting diode EDbs may include a second sub-pixel electrode 3210, a second sub-intermediate layer 3220, and a second sub-opposite electrode 3230. The second main light-emitting diode EDbm may include a second main pixel electrode 4210, a second main intermediate layer 4220, and a second main opposite electrode 4230.

The first sub-pixel electrode 1210 and the first main pixel electrode 2210 may be adjacent to each other and be disposed to be apart from each other on the planarization layer 208. Likewise, the second sub-pixel electrode 3210 and the second main pixel electrode 4210 may be adjacent to each other and be disposed to be apart from each other on the planarization layer 208. The first main pixel electrode 2210 and the second sub-pixel electrode 3210 may be also disposed to be apart from each other in the first direction (the x direction) on the planarization layer 208. In an embodiment, a distance between the first main pixel electrode 2210 and the second sub-pixel electrode 3210 may be greater than a distance between the first main pixel electrode 2210 and the first sub-pixel electrode 1210.

The first sub-pixel electrode 1210, the first main pixel electrode 2210, the second sub-pixel electrode 3210, and the second main pixel electrode 4210 may include a light-transmissive conductive layer and a reflective layer, and the light-transmissive conductive layer include a light-transmissive conductive oxide such as indium tin oxide (ITO), indium oxide (In₂O₃), or indium zinc oxide (IZO), and the reflective layer includes metal such as aluminum (Al) or silver (Ag). In an embodiment, for example, the first sub-pixel electrode 1210, the first main pixel electrode 2210, the second sub-pixel electrode 3210, and the second main pixel electrode 4210 may have a three-layered structure of ITO/Ag/ITO.

The first sub-pixel electrode 1210, the first main pixel electrode 2210, the second sub-pixel electrode 3210, and the second main pixel electrode 4210 may be electrically connected to the thin-film transistor TFT by being in contact with one of the source electrode SE and the drain electrode DE as shown in FIG. 6. In an embodiment, each of the first sub-pixel electrode 1210, the first main pixel electrode 2210, the second sub-pixel electrode 3210, and the second main pixel electrode 4210 may be in contact with one of the source electrode SE and the drain electrode DE through a contact hole defined or formed in the planarization layer 208.

The bank layer 215 may be disposed on the planarization layer 208. The bank layer 215 may define the sub-pixel P (see FIG. 5) by an opening defined therethrough to correspond to the sub-pixel P (see FIG. 5), that is, an opening exposing at least the central portion of the pixel electrode. In an embodiment, the bank layer 215 may be provided with a first sub-opening SOP1, a first main opening MOP1, a second sub-opening SOP2, a second main opening MOP2. The first sub-opening SOP1 may expose the central portion of the first sub-pixel electrode 1210, and the first main opening MOP1 may expose the central portion of the first main pixel electrode 2210. The second sub-opening SOP2 may expose the central portion of the second sub-pixel electrode 3210, and the second main opening MOP2 may expose the central portion of the second main pixel electrode 4210.

In an embodiment, as shown in FIG. 6, the bank layer 215 may increase a distance between the edge of the first sub-pixel electrode 1210 and the first sub-opposite electrode 1230 over the first sub-pixel electrode 1210 and increase a distance between the edge of the first main pixel electrode 2210 and the first main opposite electrode 2230. Similarly, the bank layer 215 may increase a distance between the edge of the second sub-pixel electrode 3210 and the second sub-opposite electrode 3230 and increase a distance between the edge of the second main pixel electrode 4210 and the second main opposite electrode 4230. Accordingly, arc or the like may be effectively prevented from occurring (or being formed) at the edge of the first sub-pixel electrode 1210, the edge of the first main pixel electrode 2210, the edge of the second sub-pixel electrode 3210, and the edge of the second main pixel electrode 4210. The bank layer 215 may include an organic material such as polyimide or HMDSO.

The first sub-intermediate layer 1220 may be disposed on the first sub-pixel electrode 1210, and the first main intermediate layer 2220 may be disposed on the first main pixel electrode 2210. The second sub-intermediate layer 3220 may be disposed on the second sub-pixel electrode 3210, and the second main intermediate layer 4220 may be disposed on the second main pixel electrode 4210. In a plan view or when viewed in a direction perpendicular to the substrate 100 (i.e., the z direction), the emission layers respectively included in the first sub-intermediate layer 1220, the first main intermediate layer 2220, the second sub-intermediate layer 3220, and the second main intermediate layer 4220 may be apart from each other.

The first sub-intermediate layer 1220, the first main intermediate layer 2220, the second sub-intermediate layer 3220, and the second main intermediate layer 4220 may include a low molecular weight material or a polymer material. In an embodiment where the first sub-intermediate layer 1220, the first main intermediate layer 2220, the second sub-intermediate layer 3220, and the second main intermediate layer 4220 include a low molecular weight material, the first sub-intermediate layer 1220, the first main intermediate layer 2220, the second sub-intermediate layer 3220, and the second main intermediate layer 4220 may have a structure in which a hole injection layer (HIL), a hole transport layer (HTL), an emission layer (EML), an electron transport layer (ETL), an electron injection layer (EIL), or the like are stacked in a single or composite structure, and may be formed using vacuum deposition.

In an embodiment where the first sub-intermediate layer 1220, the first main intermediate layer 2220, the second sub-intermediate layer 3220, and the second main intermediate layer 4220 include a polymer material, the first sub-intermediate layer 1220, the first main intermediate layer 2220, the second sub-intermediate layer 3220, and the second main intermediate layer 4220 may have a structure including an HTL and an EML. In such an embodiment, the HTL may include poly (3, 4-ethylenedioxythiophene) (PEDOT), and the EML may include a polymer material such as a polyphenylene vinylene (PPV)-based material and a polyfluorene-based material. The first sub-intermediate layer 1220, the first main intermediate layer 2220, the second sub-intermediate layer 3220, and the second main intermediate layer 4220 may be formed using screen printing, inkjet printing, laser induced thermal imaging (LITI), or the like.

In an embodiment, as shown in FIG. 7, the first sub-intermediate layer 1220 of the first sub light-emitting diode EDgs may have a tandem structure. In such an embodiment, the first sub light-emitting diode EDgs may include a first emission unit UN1, a first charge generation layer 1224, and a second emission unit UN2. The first emission unit UN1 may include a first first common layer 1221, a first lower emission layer 1222, and a first second common layer 1223, and the second emission unit UN2 may include a first third common layer 1225, a first upper emission layer 1226, and a first fourth common layer 1227.

The first upper emission layer 1226 may be disposed on the first lower emission layer 1222 to overlap the first lower emission layer 1222. The first lower emission layer 1222 and the first upper emission layer 1226 may include a polymer material or a low molecular weight organic material emitting light of a preset color. The first lower emission layer 1222 and the first upper emission layer 1226 may be configured to emit light in a preset wavelength band. In an embodiment, for example, the first lower emission layer 1222 and the first upper emission layer 1226 may be configured to emit green light. Green light may be light in a wavelength band of about 495 nm to about 580 nm.

The first first common layer 1221 may be disposed between the first sub-pixel electrode 1210 and the first lower emission layer 1222. The first first common layer 1221 may have a single layer structure or a multi-layered structure. In an embodiment, for example, where the first first common layer 1221 includes a polymer material, the first first common layer 1221 is an HTL which is a single-layered structure, and may include polyethylene dioxythiophene (PEDOT: poly-(3,4-ethylenedioxythiophene), polyaniline (PANI: polyaniline), TPD (N,N′-diphenyl-N,N′-bis(3-methylphenyl)-1,1′-bi-phenyl-4,4′-diamine) or NPB (N,N′-di(naphthalen-1-yl)-N,N′-diphenyl-benzidine). In an embodiment where the first first common layer 1221 includes a low-molecular weight material, the first first common layer 1221 may include an HIL and an HTL.

The first fourth common layer 1227 may be disposed on the first upper emission layer 1226. In another embodiment, the first fourth common layer 1227 may be omitted. In an embodiment, for example, where the first first common layer 1221, the first lower emission layer 1222, and the first upper emission layer 1226 include a polymer material, the first fourth common layer 1227 may be preferably formed. The first fourth common layer 1227 may have a single layer structure or a multi-layered structure. The first fourth common layer 1227 may include an ETL and/or an EIL. The first sub-opposite electrode 1230 may be disposed on the first fourth common layer 1227.

The first sub-intermediate layer 1220 may further include the first charge generation layer 1224. The first charge generation layer 1224 may be disposed between the first lower emission layer 1222 and the first upper emission layer 1226. The first charge generation layer 1224 may be configured to supply charges to the first emission unit UN1 including the first lower emission layer 1222, and the second emission unit UN2 including the first upper emission layer 1226.

The first sub-intermediate layer 1220 may further include the first second common layer 1223 and the first third common layer 1225. The first second common layer 1223 may be disposed between the first lower emission layer 1222 and the first charge generation layer 1224. The first third common layer 1225 may be disposed between the first charge generation layer 1224 and the first upper emission layer 1226. The first second common layer 1223 may include an ETL, and the first third common layer 1225 may include an HTL.

In such an embodiment, the first sub-intermediate layer 1220 may have a structure in which the first first common layer 1221, the first lower emission layer 1222, the first second common layer 1223, the first charge generation layer 1224, the first third common layer 1225, the first upper emission layer 1226, and the first fourth common layer 1227 are sequentially stacked one on another. The first main intermediate layer 2220 of the first main light-emitting diode EDgm, the second sub-intermediate layer 3220 of the second sub light-emitting diode EDbs, and the second main intermediate layer 4220 of the second main light-emitting diode EDbm may have a same stack structure as the tandem structure of the first sub-intermediate layer 1220.

In an embodiment, for example, the first main intermediate layer 2220 may have a structure in which the first first common layer 1221, a second lower emission layer, the first second common layer 1223, the first charge generation layer 1224, the first third common layer 1225, a second upper emission layer, and the first fourth common layer 1227 are sequentially stacked one on another. The second sub-intermediate layer 3220 may have a structure in which a third first common layer, a third lower emission layer, a third second common layer, a third charge generation layer, a third third common layer, a third upper emission layer, and a third fourth common layer are sequentially stacked. The second main intermediate layer 4220 may include a structure in which a fourth first common layer, a fourth lower emission layer, a fourth second common layer, a fourth charge generation layer, a fourth third common layer, a fourth upper emission layer, and a fourth fourth common layer are sequentially stacked. However, the third lower emission layer, the third upper emission layer, the fourth lower emission layer, and the fourth upper emission layer may be configured to emit blue light.

In such an embodiment, the first first common layer 1221, the second first common layer 2221, the third first common layer, and the fourth first common layer may be simultaneously formed through a same process using a same material. In an embodiment, a material forming the first first common layer 1221, the second first common layer 2221, the third first common layer, and the fourth first common layer may be deposited on the entire surface of the substrate 100. Similarly, the first second common layer 1223, the second second common layer 2223, the third second common layer, and the fourth second common layer may be simultaneously formed through a same process using a same material and deposited on the entire surface of the substrate 100. The first third common layer 1225, the second third common layer 2225, the third third common layer, and the fourth third common layer may be simultaneously formed through a same process using a same material and deposited on the entire surface of the substrate 100. The first fourth common layer 1227, the second fourth common layer 2227, the third fourth common layer, and the fourth fourth common layer may be simultaneously formed through a same process using a same material and deposited on the entire surface of the substrate 100. Likewise, the first charge generation layer 1224, the second charge generation layer 2224, the third charge generation layer, and the fourth charge generation layer may be simultaneously formed through a same process using a same material and deposited on the entire surface of the substrate 100.

The first sub-opposite electrode 1230 may be disposed on the first sub-intermediate layer 1220. Likewise, the first main opposite electrode 2230 may be disposed on the first main intermediate layer 2220, the second sub-opposite electrode 3230 may be disposed on the second sub-intermediate layer 3220, and the second main opposite electrode 4230 may be disposed on the second main intermediate layer 4220.

The first sub-opposite electrode 1230, the first main opposite electrode 2230, the second sub-opposite electrode 3230, and the second main opposite electrode 4230 may include a light-transmissive conductive layer and a semi-transmissive layer, where the light-transmissive conductive layer includes indium tin oxide (ITO), indium oxide (In₂O₃), or indium zinc oxide (IZO), and the semi-transmissive layer includes metal such as Al or Ag. In an embodiment, for example, the first sub-opposite electrode 1230, the first main opposite electrode 2230, the second sub-opposite electrode 3230, and the second main opposite electrode 4230 may be a semi-transmissive layer including magnesium (Mg) or Ag. The first sub-opposite electrode 1230, the first main opposite electrode 2230, the second sub-opposite electrode 3230, and the second main opposite electrode 4230 may be simultaneously formed during a same process using a same material. The first sub-opposite electrode 1230, the first main opposite electrode 2230, the second sub-opposite electrode 3230, and the second main opposite electrode 4230 may be deposited on the entire surface of the substrate 100.

Although not shown in FIG. 6, a capping layer (not shown) may be disposed on the first sub-opposite electrode 1230, the first main opposite electrode 2230, the second sub-opposite electrode 3230, and the second main opposite electrode 4230. In an embodiment, for example, the capping layer may have a single layer structure or a multi-layered structure, each layer therein including an organic material, an inorganic material, or a mixture thereof. In an embodiment, a LiF layer may be disposed on the capping layer.

The separator SEP may be disposed on the upper surface of the bank layer 215. In an embodiment of FIGS. 6 and 7, the separator SEP may be defined by a trench shape of the bank layer 215 in which a portion of the upper surface of the bank layer 215 is concave. As described with reference to FIG. 4, in a plan view or when viewed in a direction perpendicular to the substrate 100, the separator SEP may include the outer separator OSP (see FIG. 4) surrounding at least a portion of the outer portion of the sub-pixel group, and the central separator CSP (see FIG. 4) disposed between two sub-pixels configured to emit light of a same color and disposed to be adjacent to each other. In an embodiment, for example, in a plan view, the third outer separator OSP3 may surround at least a portion of the outer portion of the third sub-pixel group SG3 (see FIG. 4), and in a plan view, the second outer separator OSP2 may surround at least a portion of the outer portion of the second sub-pixel group SG2 (see FIG. 4). In a plan view, the third central separator CSP3 may be arranged between the first green sub-pixel Pg1 and the second green sub-pixel Pg2, and in a plan view, the second central separator CSP2 may be arranged between the first blue sub-pixel Pb1 and the second blue sub-pixel Pb2.

Although FIG. 6 shows an embodiment where the separator SEP may be defined by a trench shape of the bank layer 215 in which the bank layer 215 is concave, the embodiment is not limited thereto. The separator SEP may have a through hole shape passing through the bank layer 215. As shown in FIG. 6, the inner surface of the separator SEP may include a vertical inclined surface or a reverse tapered inclined surface.

Accordingly, among layers disposed on the bank layer 215, layers integrally formed on the entire surface of the substrate 100 may be disconnected or separated by the separator SEP. In an embodiment, for example, the first first common layer 1221, the second first common layer 2221, the third first common layer, and the fourth first common layer may be apart from each other by the separator SEP, and the first second common layer 1223, the second second common layer 2223, the third second common layer, and the fourth second common layer may be apart from each other by the separator SEP. The first third common layer 1225, the second third common layer 2225, the third third common layer, and the fourth third common layer may be apart from each other by the separator SEP, and the first fourth common layer 1227, the second fourth common layer 2227, the third fourth common layer, and the fourth fourth common layer may be apart from each other by the separator SEP.

In such an embodiment, the first charge generation layer 1224, the second charge generation layer 2224, the third charge generation layer, and the fourth charge generation layer may be apart from each other by the separator SEP. The first sub-opposite electrode 1230, the first main opposite electrode 2230, the second sub-opposite electrode 3230, and the second main opposite electrode 4230 may be apart from each other by the separator SEP.

Because the plurality of common layers, the charge generation layer, and the opposite electrode are layers integrally formed on the entire surface of the substrate 100, such layers may be not only separated by the separator SEP but also a remaining layer may be disposed on the separator SEP. As shown in FIG. 6, in an embodiment where the separator SEP has a trench shape, the remaining layer may be disposed on the inner surface of the separator SEP. In an embodiment, a dummy intermediate layer 220d and a dummy opposite electrode 230d may be disposed on the inner surface of the separator SEP. The dummy intermediate layer 220d may include a first dummy common layer 221d, a second dummy common layer 223d, a dummy charge generation layer 224d, a third dummy common layer 225d, and a fourth dummy common layer 227d.

The first dummy common layer 221d may include a same material as the material of the first first common layer 1221, the second first common layer 2221, the third first common layer and the fourth first common layer and be formed by a same process, but may be apart from the first first common layer 1221, the second first common layer 2221, the third first common layer and the fourth first common layer. The second dummy common layer 223d may include a same material as the material of the first second common layer 1223, the second second common layer 2223, the third second common layer and the fourth second common layer and be formed by a same process, but may be apart from the first second common layer 1223, the second second common layer 2223, the third second common layer and the fourth second common layer. The third dummy common layer 225d may include a same material as the material of the first third common layer 1225, the second third common layer 2225, the third third common layer and the fourth third common layer and be formed by a same process, but may be apart from the first third common layer 1225, the second third common layer 2225, the third third common layer and the fourth third common layer. The fourth dummy common layer 227d may include a same material as the material of the first fourth common layer 1227, the second fourth common layer 2227, the third fourth common layer and the fourth fourth common layer and be formed by a same process, but may be apart from the first fourth common layer 1227, the second fourth common layer 2227, the third fourth common layer and the fourth fourth common layer.

The dummy charge generation layer 224d may include a same material as the first charge generation layer 1224, the second charge generation layer 2224, the third charge generation layer, and the fourth charge generation layer and be formed by a same process, but may be apart from the first charge generation layer 1224, the second charge generation layer 2224, the third charge generation layer, and the fourth charge generation layer. The dummy opposite electrode 230d may include a same material as the material of the first sub-opposite electrode 1230, the first main opposite electrode 2230, the second sub-opposite electrode 3230, and the second main opposite electrode 4230 and be formed by a same process, but may be apart from the first sub-opposite electrode 1230, the first main opposite electrode 2230, the second sub-opposite electrode 3230, and the second main opposite electrode 4230.

As described above, each of the first sub light-emitting diode EDgs, the first main light-emitting diode EDgm, the second sub light-emitting diode EDbs, and the second main light-emitting diode EDbm may include layers integrally formed on the entire surface of the substrate 100. However, between the light-emitting diodes ED arranged to be adjacent to each other among the plurality of light-emitting diodes ED, a leakage current may flow due to the above-described integrally formed layers. Particularly, because the charge generation layer is vulnerable to a leakage current, in the case where the light-emitting diode ED has a tandem structure, the charge generation layer may be more vulnerable to the leakage current and color mixing defects.

For example, when a current is supplied to the first main light-emitting diode EDgm, the current may also be supplied to the adjacent second sub light-emitting diode EDbs due to the leakage current of the plurality of common layers or the charge generation layer. As a result, because not only green light may be emitted from the first main light-emitting diode EDgm but also blue light may be emitted from the second sub light-emitting diode EDbs, deterioration in display quality such as deterioration in color purity may occur.

Likewise, when a current is supplied to the first sub light-emitting diode EDgs, the current may also be supplied to the adjacent first main light-emitting diode EDgm due to the leakage current of the plurality of common layers or the charge generation layer. As a result, in the driver non-viewable mode, light may be emitted not only from the first sub light-emitting diode EDgs, but also from both the first sub light-emitting diode EDgs and the first main light-emitting diode EDgm. In this case, even in the driver non-viewable mode, there is a risk that a user sitting in the driver's seat will see the images on the display apparatus 1, and there may be issues with unclear mode distinctions between driver non-viewable mode and driver viewable modes, resulting in poor display quality.

In the display apparatus 1 according to an embodiment, the separator SEP is disposed on the upper surface of the bank layer 215, such that the leakage current, the color mixing defect, or the like may be effectively prevented. In such an embodiment, the third outer separator OSP3 and the second outer separator OSP2 may be arranged between the first main light-emitting diode EDgm and the second sub light-emitting diode EDbs configured to emit light of different colors. In an embodiment, two separators SEP are arranged between adjacent light-emitting diodes ED configured to emit light of different colors, such that the plurality of common layers, the charge generation layer, and the opposite electrode are separated twice by two separators SEP, and thus, the leakage current and the color mixing defects may be efficiently prevented.

In addition, in the display apparatus 1 according to an embodiment, the separator SEP is also arranged between two adjacent light-emitting diodes ED configured to emit light of a same color, such that the leakage current may be effectively prevented even between the sub-pixels of a same color. In an embodiment, the third central separator CSP3 is arranged between the first sub light-emitting diode EDgs and the first main light-emitting diode EDgm, and the second central separator CSP2 may be arranged between the second sub light-emitting diode EDbs and the second main light-emitting diode EDbm. In such an embodiment, because the separator SEP is arranged even between two adjacent light-emitting diodes ED configured to emit light of the same color, the leakage current may be effectively prevented even between the sub-pixels arranged in one sub-pixel group, and more clear distinction between the driver viewable mode and the driver non-viewable mode may be made. That is, the display apparatus 1 according to an embodiment may effectively prevent a user sitting on a driver seat from seeing images on the display apparatus 1 while driving in the driver non-viewable mode.

The encapsulation layer 400 configured to encapsulate the plurality of light-emitting diodes ED may be disposed on the plurality of light-emitting diodes ED. The encapsulation layer 400 may include at least one inorganic encapsulation layer and at least one organic encapsulation layer. The at least one inorganic encapsulation layer may include at least one inorganic material selected from aluminum oxide (Al₂O₃), titanium oxide (TiO₂), tantalum oxide (Ta₂O₅), zinc oxide (ZnO), silicon oxide (SiOₓ), silicon nitride (SiNₓ), and silicon oxynitride (SiON). The at least one organic encapsulation layer may include a polymer-based material. The polymer-based material may include an acryl-based resin, an epoxy-based resin, polyimide, and polyethylene. In an embodiment, the at least one organic encapsulation layer may include acrylate.

In an embodiment, as shown in FIG. 6, the encapsulation layer 400 may include a first inorganic encapsulation layer 410, a second inorganic encapsulation layer 430, and an organic encapsulation layer 420 disposed between the first inorganic encapsulation layer 410 and the second inorganic encapsulation layer 430. The organic encapsulation layer 420 may cover irregularities of the plurality of light-emitting diodes ED and provide a flat upper surface.

The light-blocking layer 500 may be disposed on the encapsulation layer 400. The light-blocking layer 500 may include the first light-blocking line 510 (see FIG. 5), the second light-blocking line 520, and an overcoat layer 530.

The first light-blocking line 510 (see FIG. 5) and the second light-blocking line 520 may be disposed on the second inorganic encapsulation layer 430. The first light-blocking line 510 (see FIG. 5) and the second light-blocking line 520 may include a light-absorbing material and/or a low reflective material. The first light-blocking line 510 (see FIG. 5) and the second light-blocking line 520 may define light-transmissive openings overlapping the openings OP (see FIG. 5) of the bank layer 215. That is, the body portion of the first light-blocking line 510 (see FIG. 5) and the second light-blocking line 520 may overlap the body portion of the bank layer 215. The body portion of the first light-blocking line 510 (see FIG. 5) and the second light-blocking line 520 is distinct from the light-transmissive openings and denotes a portion having a preset volume. Likewise, the body portion of the bank layer 215 is distinct from the openings OP (see FIG. 5) and denotes a portion having a preset volume.

The body portion of the first light-blocking line 510 (see FIG. 5) and the second light-blocking line 520 may define a light-blocking area SHA configured to block light emitted from the light-emitting diodes ED. The light-transmissive openings of the first light-blocking line 510 (see FIG. 5) and the second light-blocking line 520 may define a transmissive area TA through which light emitted from the light-emitting diodes ED may pass. In an embodiment where light emitted from the light-emitting diodes ED has a preset angle or more, the emitted light may be absorbed by the first light-blocking line 510 (see FIG. 5) and the second light-blocking line 520. Accordingly, light emitted by some of the sub-pixels may be blocked depending on a user's position.

The overcoat layer 530 may be disposed on the first light-blocking line 510 (see FIG. 5) and the second light-blocking line 520. The overcoat layer 530 may provide a flat upper surface by burying the light-transmissive openings of the first light-blocking line 510 (see FIG. 5) and the second light-blocking line 520. The overcoat layer 530 may include a light-transmissive organic material. In an embodiment, for example, the overcoat layer 530 may include acrylic resin (e.g., polymethyl methacrylate, polyacrylic acid, etc.), ethylhexyl acrylate, pentafluoropropyl acrylate, polyethylene glycol dimethacrylate, poly(ethylene glycol) dimethacrylate or ethylene glycol dimethacrylate.

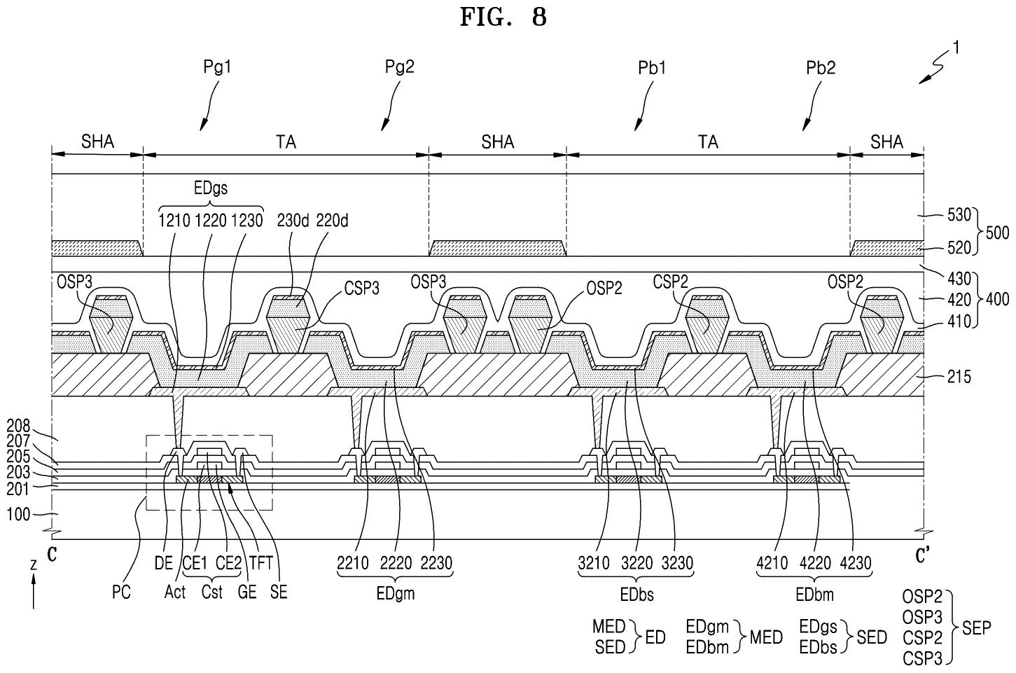

FIG. 8 is a schematic cross-sectional view of a display apparatus according to another embodiment. The cross-sectional view in FIG. 8 is substantially the same as the cross-sectional view shown in FIG. 6 except for the separator SEP. The same or like elements shown in FIG. 8 are labeled with the same reference characters as used above to describe the embodiment of the display apparatus shown in FIGS. 4 to 7, and any repetitive detailed description thereof will hereinafter be omitted or simplified.

Referring to FIG. 8, in an embodiment, the separator SEP may be disposed on the upper surface of the bank layer 215. As described with reference to FIG. 4, when viewed in a direction perpendicular to the substrate 100, the separator SEP may include the outer separator OSP (see FIG. 4) surrounding at least a portion of the outer portion of the sub-pixel group, and the central separator CSP (see FIG. 4) disposed between two sub-pixels configured to emit light of a same color and disposed to be adjacent to each other. In an embodiment, for example, in a plan view, the third outer separator OSP3 may surround at least a portion of the outer portion of the third sub-pixel group SG3 (see FIG. 4), and in a plan view, the second outer separator OSP2 may surround at least a portion of the outer portion of the second sub-pixel group SG2 (see FIG. 4). In a plan view, the third central separator CSP3 may be arranged between the first green sub-pixel Pg1 and the second green sub-pixel Pg2, and in a plan view, the second central separator CSP2 may be arranged between the first blue sub-pixel Pb1 and the second blue sub-pixel Pb2.

The separator SEP may be defined by a separate structure disposed on the upper surface of the bank layer 215. In an embodiment, for example, the separator SEP may be a structure including the same material as the material of the spacer SPC (see FIG. 4) disposed on the bank layer 215 and formed through the same process as a process of forming the spacer SPC. The separator SEP may include an organic insulating material. In an embodiment, for example, the separator SEP may include benzocyclobutene (BCB), polyimide, hexamethyldisiloxane (HMDSO), polymethylmethacrylate (PMMA), polystyrene, polymer derivatives having a phenol-based group, an acryl-based polymer, an imide-based polymer, an aryl ether-based polymer, an amide-based polymer, a fluorine-based polymer, a p-xylene-based polymer, a vinyl alcohol-based polymer, or a mixture thereof.

The separator SEP may include a reverse tapered inclined surface as a lateral surface. In such an embodiment where the lateral surface of the separator SEP includes a reverse tapered inclined surface, the width in a direction (a +z direction) opposite a direction to the substrate 100 of the separator SEP is greater than the width in a direction (a −z direction) to the substrate 100 of the separator SEP.

The separator SEP whose lateral surface includes a reverse tapered inclined surface may be formed using a negative photoresist. A photoresist may be classified into a positive photoresist and a negative photoresist. A positive photoresist refers to a photoresist whose solubility in a developer increases by exposure, and a negative photoresist refers to a photoresist whose solubility in a developer decreases by exposure.

Accordingly, when developing a partially exposed positive photoresist, a pattern may be created with the exposed portion removed, and when developing a partially exposed negative photoresist, a pattern may be created with the unexposed portion removed. When exposing a layer formed by applying a negative photoresist using a mask, not only a portion disposed below a transmissive portion of the mask but also a portion adjacent to the bottom of the transmissive portion may be exposed. Specifically, a portion adjacent to the bottom of the transmissive portion may increase in solubility in the developer from the top, which is in the direction to a light source, to the bottom, which is in the direction opposite the light source. Accordingly, a pattern having the reverse tapered inclined surface may be formed.

Accordingly, among layers disposed on the bank layer 215, layers integrally formed on the entire surface of the substrate 100 may be disconnected or separated by the separator SEP. In an embodiment, for example, the plurality of common layers, the charge generation layer, and the opposite electrode may be disconnected or apart from each other by the separator SEP.

Because the plurality of common layers, the charge generation layer, and the opposite electrode are layers integrally formed on the entire surface of the substrate 100, they may be not only separated by the separator SEP but also a remaining layer may be disposed on the separator SEP. As shown in FIG. 8, in an embodiment where the separator SEP is a structure having a reverse tapered inclined surface, the remaining layer may be disposed on the separator SEP. Specifically, the dummy intermediate layer 220d and the dummy opposite electrode 230d may be disposed on the separator SEP.

As described above, between the light-emitting diodes ED arranged to be adjacent to each other among the plurality of light-emitting diodes ED, a leakage current may flow due to the integrally formed layers. However, in the display apparatus 1 according to an embodiment, because the separator SEP is disposed on the upper surface of the bank layer 215, the above-described leakage current may be prevented.

In an embodiment, two separators SEP are arranged between two adjacent light-emitting diodes ED configured to emit light of different colors, such that the plurality of common layers, the charge generation layer, and the opposite electrode are separated twice by the two separators SEP, and thus, the color mixing defects between the sub-pixels of different colors may be efficiently prevented.

In the display apparatus 1 according to an embodiment, because the separator SEP is also arranged between two adjacent light-emitting diodes ED configured to emit light of a same color, the leakage current may be effectively prevented even between the sub-pixels of a same color. Accordingly, because the display apparatus 1 allows clear mode distinction between the driver viewable mode and the driver non-viewable mode, a user sitting in a driver seat may be effectively prevented from seeing images on the display apparatus 1 while driving in the driver non-viewable mode.

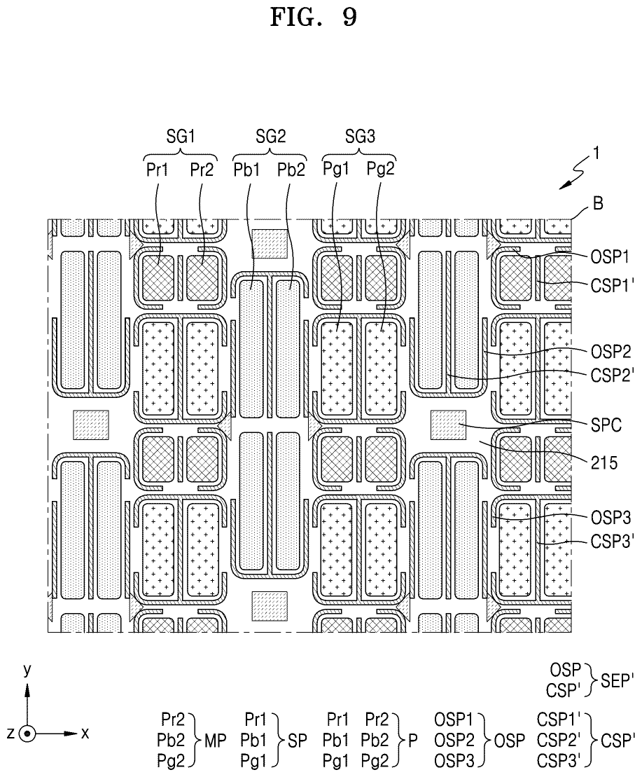

FIG. 9 is an enlarged plan view of a display apparatus according to another embodiment. The plan view in FIG. 9 is substantially the same as the plan view shown in FIG. 4 except for the central separator CSP′. The same or like elements shown in FIG. 9 are labeled with the same reference characters as used above to describe the embodiment of the display apparatus shown in FIGS. 4 to 7, and any repetitive detailed description thereof will hereinafter be omitted or simplified.

Referring to FIG. 9, in an embodiment, the separator SEP′ may be disposed on the upper surface of the bank layer 215. The separator SEP′ may surround at least a portion of the outer portion of each of the plurality of sub-pixels P. In such an embodiment, the separator SEP′ may include the outer separator OSP and the central separator CSP′.

The outer separator OSP may be arranged to surround at least a portion of the outer portion of each sub-pixel group when viewed in a direction (a z direction) perpendicular to the substrate 100. The outer separator OSP may include a first outer separator OSP1 surrounding at least a portion of the outer portion of the first sub-pixel group SG1, a second outer separator OSP2 surrounding at least a portion of the outer portion of the second sub-pixel group SG2, and a third outer separator OSP3 surrounding at least a portion of the outer portion of the third sub-pixel group SG3.

When viewed in a direction (the z direction) perpendicular to the substrate 100, the central separator CSP′ may be arranged between sub-pixels P configured to emit light of a same color and arranged to be adjacent to each other. The central separator CSP′ may be arranged between the main sub-pixel MP and the sub sub-pixel SP. That is, the central separator CSP′ may be arranged between the main opening MOP (see FIG. 5) and the sub-opening SOP (see FIG. 5). In such an embodiment, the central separator CSP′ may include a first central separator CSP1′ arranged between the first red sub-pixel Pr1 and the second red sub-pixel Pr2, a second central separator CSP2′ arranged between the first blue sub-pixel Pb1 and the second blue sub-pixel Pb2, and a third central separator CSP3′ arranged between the first green sub-pixel Pg1 and the second green sub-pixel Pg2.

The central separator CSP′ may extend in the second direction (the y direction). The central separator CSP′ may be arranged between the main sub-pixel MP and the sub sub-pixel SP and arranged to be parallel to the lateral surfaces facing each other, of each of the main sub-pixel MP and the sub sub-pixel SP.

In an embodiment, the central separators CSP′ arranged to be adjacent to each other may be arranged to be apart from each other. That is, the central separators CSP adjacent to each other may be formed to be separated without being connected to each other. In an embodiment, for example, as shown in FIG. 9, where the first sub-pixel group SG1 and the third sub-pixel group SG3 are alternately arranged in the second direction (the y direction), the first central separator CSP1′ and the third central separator CSP3′ may be formed to be apart from each other without being connected to each other. In an embodiment, where two second sub-pixel groups SG2 are arranged side-by-side in the second direction (the y direction) without the spacer SPC therebetween, two second central separators CSP2′ adjacent to each other may be formed to be apart from each other without being connected to each other.

As described above, between the light-emitting diodes ED arranged to be adjacent to each other among the plurality of light-emitting diodes ED, a leakage current may flow due to the integrally formed layers. In the display apparatus 1 according to an embodiment, the separator SEP′ is disposed on the upper surface of the bank layer 215, such that the above-described leakage current may be effectively prevented.

In an embodiment, two separators SEP′ are arranged between two sub-pixels P configured to emit light of different colors, such that the plurality of common layers, the charge generation layer, and the opposite electrode are separated two separators SEP′, and thus, the color mixing defects between the sub-pixels P of different colors may be efficiently prevented.

In addition, in the display apparatus 1 according to an embodiment, because the separator SEP′ is also arranged between two adjacent sub-pixels P configured to emit light of a same color, the leakage current may be effectively prevented even between the sub-pixels P of the same color. Accordingly, because the display apparatus 1 allows clear mode distinction between the driver viewable mode and the driver non-viewable mode, a user sitting in a driver seat may be effectively prevented from seeing images on the display apparatus 1 while driving in the driver non-viewable mode.

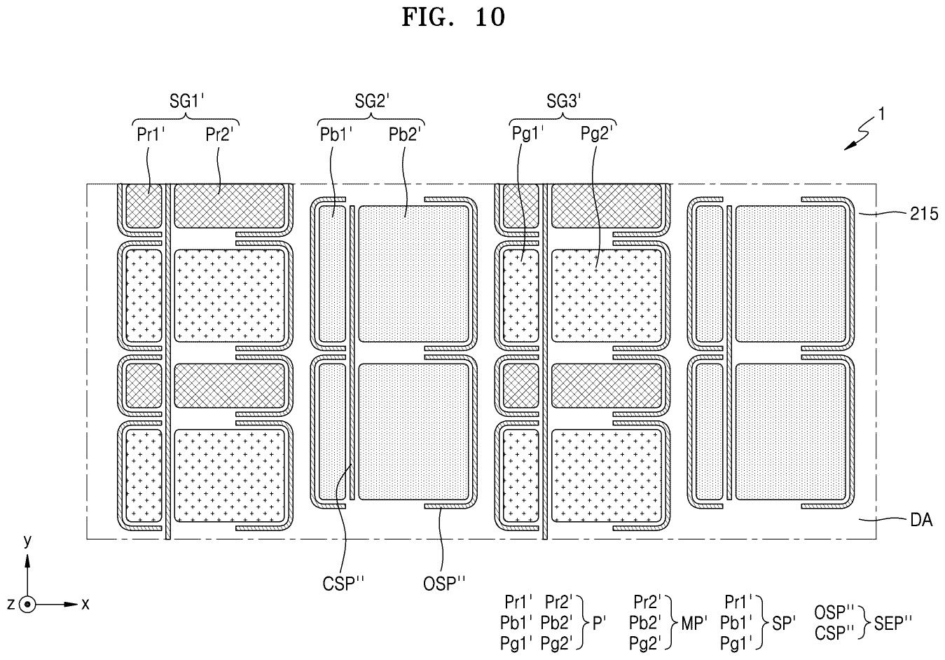

FIG. 10 is an enlarged plan view of a display apparatus according to another embodiment. The plan view in FIG. 10 is substantially the same as the plan view shown in FIG. 4 except for the subpixel P′. The same or like elements shown in FIG. 10 are labeled with the same reference characters as used above to describe the embodiment of the display apparatus shown in FIGS. 4 to 7, and any repetitive detailed description thereof will hereinafter be omitted or simplified.

In an embodiment, referring to FIG. 10, a plurality of sub-pixels P′ may be arranged in the display area DA. In such an embodiment, a first sub-pixel group SG1′ configured to emit red light, a second sub-pixel group SG2′ configured to emit blue light, and a third sub-pixel group SG3′ configured to emit green light may be arranged in the display area DA. The first sub-pixel group SG1′ may include a first red sub-pixel Pr1′ and a second red sub-pixel Pr2′ that are driven independently of each other, the second sub-pixel group SG2′ may include a first blue sub-pixel Pb1′ and a second blue sub-pixel Pb2′ that are driven independently of each other, and the third sub-pixel group SG3′ may include a first green sub-pixel Pg1′ and a second green sub-pixel Pg2′ that are driven independently of each other.

In such an embodiment, light emitted from the first red sub-pixel Pr1′, the first blue sub-pixel Pb1′, and the first green sub-pixel Pg1′ may be absorbed in the second light-blocking line 520 (see FIG. 5) and may not be viewed to a user sitting in the driver seat. Accordingly, the first red sub-pixel Pr1′, the first blue sub-pixel Pb1′, and the first green sub-pixel Pg1′ may be sub-pixels driven in the driver non-viewable mode and be denoted by sub sub-pixels SP′. Light emitted from the second red sub-pixel Pr2′, the second blue sub-pixel Pb2′, and the second green sub-pixel Pg2′ may travel to a path not passing through the second light-blocking line 520 (see FIG. 5) and may be viewed to a user sitting in the driver seat. Accordingly, the second red sub-pixel Pr2′, the second blue sub-pixel Pb2′, and the second green sub-pixel Pg2′ may be sub-pixels driven in the driver viewable mode and be denoted by main sub-pixels MP′.

In such an embodiment, the sub sub-pixel SP′ and the main sub-pixel MP′ may be different in size (or planar area). In an embodiment, for example, the area of the second red sub-pixel Pr2′ may be greater than the area of the first red sub-pixel Pr1′, the area of the second blue sub-pixel Pb2′ may be greater than the area of the first blue sub-pixel Pb1′, and the area of the second green sub-pixel Pg2′ may be greater than the area of the first green sub-pixel Pg1′. However, the embodiment is not limited thereto and the area of the sub sub-pixel SP′ may be greater than the area of the main sub-pixel MP′ depending on the needs of the driver viewable mode and driver non-viewable mode settings.

In an embodiment, the display apparatus 1 may further include a separator SEP″. In such an embodiment where the sub-pixel P′ is arranged as in FIG. 10, the separator SEP″ may be arranged to surround at least a portion of the outer portion of a plurality of sub-pixels P′. The separator SEP″ may include a central separator CSP″ and an outer separator OSP″. The central separator CSP″ may be arranged between the main sub-pixels MP′ and MP″ and the sub sub-pixels SP′ and SP″. The outer separator OSP″ may surround at least a portion of the outer portion of the sub-pixel group. In such an embodiment where the area of the main sub-pixels MP′ and MP″ is greater than the area of the sub sub-pixels SP′ and SP″ as in FIG. 10, the size of the outer separator OSP″ surrounding the outer portion of the main sub-pixels MP′ and MP″ may be greater than the size of the outer separator OSP″ surrounding the outer portion of the sub sub-pixels SP′ and SP″.

As a result, in the display apparatus 1 according to an embodiment, because the separator SEP″ is disposed on the upper surface of the bank layer 215, the leakage current between the adjacent sub-pixels may be effectively prevented. In an embodiment where the areas of the main sub-pixel MP′ and the sub sub-pixel SP′ are provided to be different from each other as in FIG. 10, the leakage current may be efficiently prevented by adjusting the size of the separator SEP″. Accordingly, the display apparatus 1 according to an embodiment may be configured to efficiently prevent color mixing defects that may occur between the sub-pixels of different colors and clarify mode distinction between the sub-pixels of a same color.

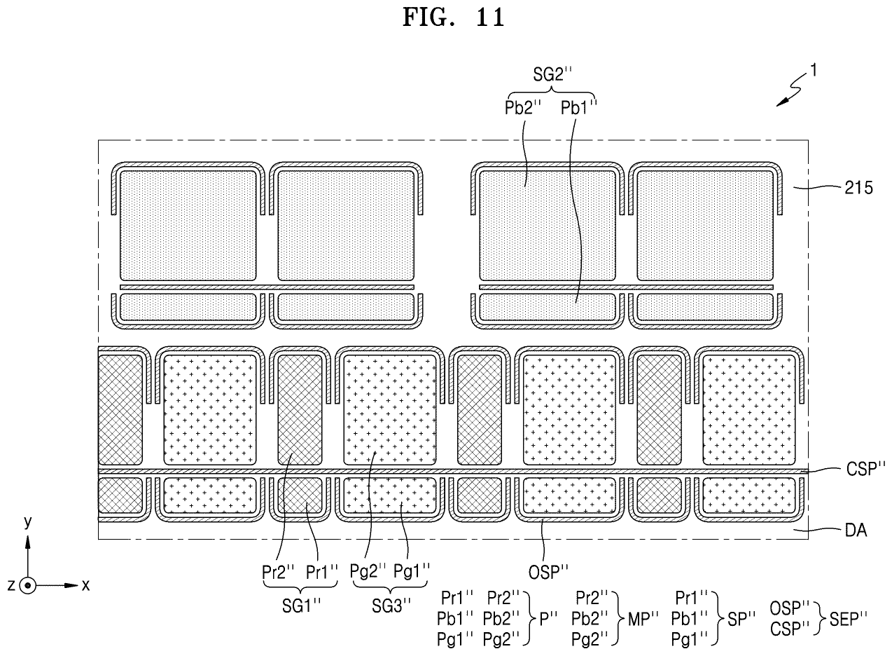

FIG. 11 is an enlarged plan view of a display apparatus according to another embodiment. The plan view in FIG. 11 is substantially the same as the plan view shown in FIG. 4 except for the sub-pixel P″. The same or like elements shown in FIG. 11 are labeled with the same reference characters as used above to describe the embodiment of the display apparatus shown in FIGS. 4 to 7, and any repetitive detailed description thereof will hereinafter be omitted or simplified.

Referring to FIG. 11, in an embodiment, a plurality of sub-pixels P″ may be arranged in the display area DA. In such an embodiment, a first sub-pixel group SG1″ configured to emit red light, a second sub-pixel group SG2″ configured to emit blue light, and a third sub-pixel group SG3″ configured to emit green light may be arranged in the display area DA. The first sub-pixel group SG1″ may include a first red sub-pixel Pr1″ and a second red sub-pixel Pr2″ that are driven independently of each other, the second sub-pixel group SG2″ may include a first blue sub-pixel Pb1″ and a second blue sub-pixel Pb2″ that are driven independently of each other, and the third sub-pixel group SG3″ may include a first green sub-pixel Pg1″ and a second green sub-pixel Pg2″ that are driven independently of each other.

In an embodiment, light emitted from the first red sub-pixel Pr1″, the first blue sub-pixel Pb1″, and the first green sub-pixel Pg1″ may be absorbed in the second light-blocking line 520 (see FIG. 5) and may not be viewed to a user sitting in the driver seat. Accordingly, the first red sub-pixel Pr1″, the first blue sub-pixel Pb1″, and the first green sub-pixel Pg1″ may be sub-pixels driven in the driver non-viewable mode and be denoted by sub sub-pixels SP″. Light emitted from the second red sub-pixel Pr2″, the second blue sub-pixel Pb2″, and the second green sub-pixel Pg2″ may travel to a path not passing through the second light-blocking line 520 (see FIG. 5) and may be viewed to a user sitting in the driver seat. Accordingly, the second red sub-pixel Pr2″, the second blue sub-pixel Pb2″, and the second green sub-pixel Pg2″ may be sub-pixels driven in the driver viewable mode and be denoted by main sub-pixels MP″.

Sub-pixels P″ in each sub-pixel group may be apart from each other in the second direction (the y direction). In an embodiment, for example, the first red sub-pixel Pr1″ and the second red sub-pixel Pr2″ in the first sub-pixel group SG1″ may be apart from each other in the second direction (the y direction), the first blue sub-pixel Pb1″ and the second blue sub-pixel Pb2″ in the second sub-pixel group SG2″ may be apart from each other in the second direction (the y direction), and the first green sub-pixel Pg1″ and the second green sub-pixel Pg2″ in the third sub-pixel group SG3″ may be apart from each other in the first direction (the x direction).

The first sub-pixel group SG1″ and the second sub-pixel group SG2″ may be apart from each other in the second direction (the y direction). The first sub-pixel group SG1″ and the third sub-pixel group SG3″ may be apart from each other in the first direction (the x direction). The first sub-pixel group SG1″ and the third sub-pixel group SG3″ may be alternately arranged in the first direction (the x direction). The third sub-pixel group SG3″ and the second sub-pixel group SG2″ may be apart from each other in the second direction (the y direction). That is, the first red sub-pixel Pr1″ and the first green sub-pixel Pg1″ may be apart from each other in the first direction (the x direction), and the second red sub-pixel Pr2″ and the second green sub-pixel Pg2″ may be apart from each other in the first direction (the x direction). The first blue sub-pixel Pb1″ may be apart from the second red sub-pixel Pr2″ and the second green sub-pixel Pg2″ in the second direction (the y direction).

In an embodiment where the main sub-pixel MP″ and the sub sub-pixel SP″ are apart from each other in the second direction (the y direction), the configuration of the plurality of light-blocking lines BL (see FIG. 5) may change. In an embodiment where the main sub-pixel MP″ and the sub sub-pixel SP″ are arranged as in FIG. 11, the plurality of first light-blocking lines 510 (see FIG. 5) may extend in the second direction (the y direction), and the plurality of second light-blocking lines 520 (see FIG. 5) may extend in the first direction (the x direction).

In addition, the display apparatus 1 may further include the separator SEP″. In an embodiment where the sub-pixel P″ is arranged as in FIG. 11, the separator SEP″ may be arranged to surround at least a portion of the outer portion of a plurality of sub-pixels P. The separator SEP″ may include and the central separator CSP″ and the outer separator OSP″. The outer separator OSP″ may surround at least a portion of the outer portion of the sub-pixel group. The central separator CSP″ may be arranged between the main sub-pixel MP″ and the sub sub-pixel SP″ and may extend in the first direction (the x direction).

As a result, in the display apparatus 1 according to an embodiment, because the separator SEP″ is disposed on the upper surface of the bank layer 215, the leakage current between the adjacent sub-pixels may be effectively prevented. In an embodiment where the arrangement directions of the main sub-pixel MP′ and the sub sub-pixel SP′ are provided to be different from each other as in FIG. 11, the leakage current may be efficiently prevented by adjusting the configuration of the separator SEP″ together. Accordingly, the display apparatus 1 according to an embodiment may be configured to efficiently prevent color mixing defects that may occur between the sub-pixels of different colors and clarify mode distinction between the sub-pixels of a same color.

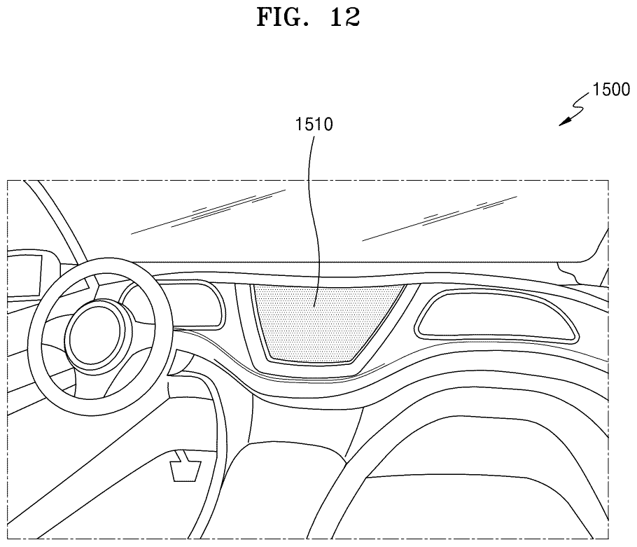

FIG. 12 is a schematic view of a vehicle including a display apparatus according to an embodiment.

FIG. 12 shows a vehicle display apparatus 1500 as a display apparatus according to an embodiment. The vehicle display apparatus 1500 may include a center information display (CID) 1510. The CID 1510 is located between the driver's seat and the passenger seat, and may provide different images to a user located in the driver's seat, a user located in the passenger seat, and/or a user located in the back seat. In an embodiment, for example, the CID 1510 may be configured to display navigation or vehicle operation information to the user located in the driver's seat. In an embodiment, the CID 1510 may be configured to display entertainment contents to the user located in the passenger seat and/or the back seat.

In an embodiment, as shown in FIG. 12, the CID 1510 may be separated from a cluster display apparatus in the driver's seat and a display apparatus in the passenger seat, the embodiment is not limited thereto. The CID 1510 may extend and be integrally connected to the cluster display apparatus in the driver's seat and the display apparatus in the passenger seat.

The display apparatus according to the embodiment may be applied to various electronic apparatuses. An electronic apparatus according to an embodiment of the present disclosure may include the display apparatus (e.g., the display apparatus of FIG. 1) described above, and may further include modules or apparatuses having additional functions in addition to the display apparatus.

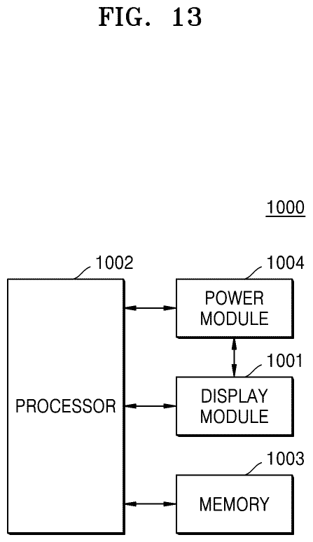

FIG. 13 is a block diagram of an electronic apparatus according to an embodiment.

Referring to FIG. 13, an electronic apparatus 1000 according to an embodiment may include a display module 1001, a processor 1002, a memory 1003, and a power module 1004.

The processor 1002 may include at least one of a central processing unit (CPU), an application processor (AP), a graphic processing unit (GPU), a communication processor (CP), an image signal processor (ISP), and a controller.

The memory 1003 may store data information necessary for the operation of the processor 1002 or the display module 1001. When the processor 1002 executes an application stored in the memory 1003, an image data signal and/or an input control signal may be transmitted to the display module 1001, and the display module 1001 may process a signal received and output image information through a display screen.

The power module 1004 may include a power supply module such as a power adapter or a battery device, and a power conversion module that converts the power supplied by the power supply module to generate power necessary for the operation of the electronic apparatus 1000.

At least one of the components of the electronic apparatus 1000 described above may be included in the display apparatus according to the embodiments described above. In addition, a part among the individual modules functionally included in one module may be included in the display apparatus, and another part may be provided separately from the display apparatus. For example, the display apparatus may include the display module 1001, and the processor 1002, the memory 1003, and the power module 1004 may be provided in the form of other apparatuses within the electronic apparatus 1000 except for the display apparatus.

In an embodiment, the display module 1001 included in the display apparatus may drive based on the image data signal and the input control signal received from the processor 1002.

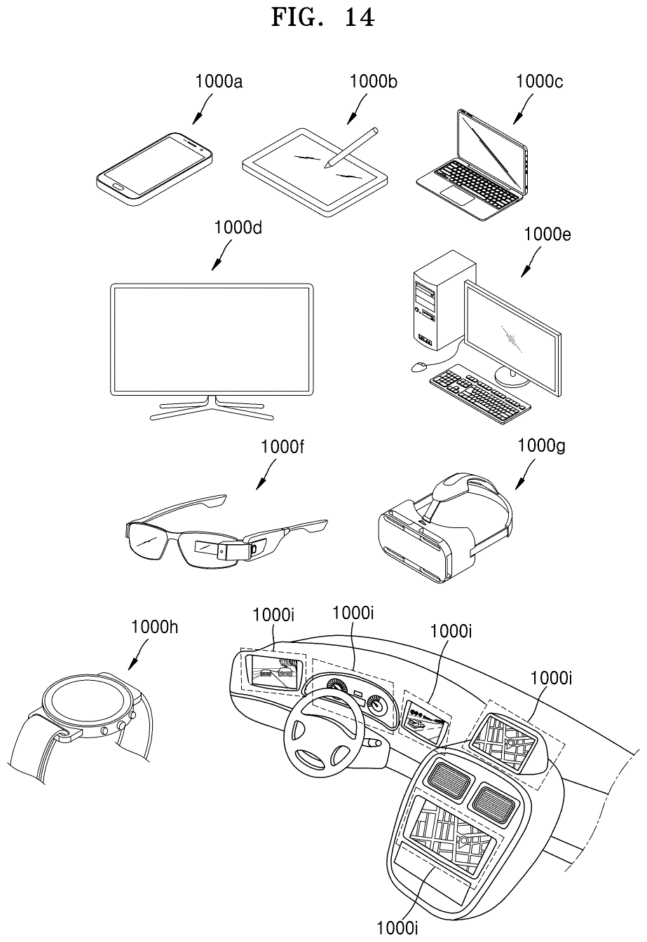

FIG. 14 is schematic diagrams of electronic apparatuses according to various embodiments.

Referring to FIG. 14, various electronic apparatuses to which display apparatuses according to embodiments are applied may include not only image display electronic apparatuses such as a smart phone 1000a, a tablet PC 1000b, a laptop 1000c, a TV 1000d, and a desk monitor 1000e, but also a wearable electronic device including display modules such as smart glasses 1000f, a head mounted display 1000g, and a smart watch 1000h, and a vehicle electronic device 1000i including a dashboard, a center fascia, and display modules such as a CID (Center Information Display) and a room mirror display disposed in the dashboard.

In embodiments of the display apparatus having the above configuration, a separator is arranged even between two adjacent light-emitting diodes configured to emit light of a same color, the leakage current may be effectively prevented even between the sub-pixels arranged in one sub-pixel group, and more clear distinction between the driver viewable mode and the driver non-viewable mode may be made.

The invention should not be construed as being limited to the embodiments set forth herein. Rather, these embodiments are provided so that this disclosure will be thorough and complete and will fully convey the concept of the invention to those skilled in the art.

While the invention has been particularly shown and described with reference to embodiments thereof, it will be understood by those of ordinary skill in the art that various changes in form and details may be made therein without departing from the spirit or scope of the invention as defined by the following claims.

What is claimed is:

1. A display apparatus comprising:
a substrate;
a first main light-emitting diode disposed on the substrate;
a first sub light-emitting diode disposed on the substrate to be adjacent to the first main light-emitting diode, wherein the first sub light-emitting diode emits light of a same color as the first main light-emitting diode;
a bank layer defining a first main opening exposing the first main light-emitting diode and a first sub-opening exposing the first sub light-emitting diode; and
a first central separator disposed on an upper surface of the bank layer, wherein when viewed in a direction perpendicular to the substrate, the first central separator is arranged between the first main opening and the first sub-opening.

2. The display apparatus of claim 1, wherein the first central separator is defined by a trench shape of the bank layer in which a portion of the upper surface of the bank layer is concave.

3. The display apparatus of claim 1, wherein the first central separator is defined by a structure disposed on the upper surface of the bank layer, and a lateral surface of the first central separator includes a reverse tapered inclined surface.

4. The display apparatus of claim 1, wherein the first main light-emitting diode includes a first main pixel electrode, a first main intermediate layer on the first main pixel electrode, and a first main opposite electrode on the first main intermediate layer,
the first sub light-emitting diode includes a first sub-pixel electrode, a first sub-intermediate layer on the first sub-pixel electrode, and a first sub-opposite electrode on the first sub-intermediate layer,
the first main intermediate layer and the first sub-intermediate layer are apart from each other with the first central separator therebetween, and
the first main opposite electrode and the first sub-opposite electrode are apart from each other with the first central separator therebetween.

5. The display apparatus of claim 4, further comprising:
a dummy intermediate layer disposed between the first main intermediate layer and the first sub-intermediate layer when viewed in the direction perpendicular to the substrate; and
a dummy opposite electrode disposed between the first main opposite electrode and the first sub-opposite electrode when viewed in the direction perpendicular to the substrate.

6. The display apparatus of claim 5, wherein the dummy intermediate layer and the dummy opposite electrode are disposed on the first central separator.

7. The display apparatus of claim 5, wherein the dummy intermediate layer is not electrically connected to the first main intermediate layer and the first sub-intermediate layer, and the dummy opposite electrode is not electrically connected to the first main opposite electrode and the first sub-intermediate layer.

8. The display apparatus of claim 4, wherein each of the first main intermediate layer and the first sub-intermediate layer has a stacked structure including a lower emission layer and an upper emission layer on the lower emission layer.

9. The display apparatus of claim 8, wherein each of the first main intermediate layer and the first sub-intermediate layer further includes a charge generation layer disposed between the lower emission layer and the upper emission layer.

10. The display apparatus of claim 1, further comprising:
a second main light-emitting diode disposed on the substrate, wherein the second main light-emitting diode emits light of a color different from a color of light of the first main light-emitting diode; and
a second sub light-emitting diode disposed on the substrate to be adjacent to the second main light-emitting diode, wherein the second sub light-emitting diode emits light of a same color as a color of light of the second main light-emitting diode,
wherein the bank layer further defines a second main opening exposing the second main light-emitting diode, and a second sub-opening exposing the second sub light-emitting diode.

11. The display apparatus of claim 10, further comprising a second central separator disposed on the upper surface of the bank layer, wherein when viewed in the direction perpendicular to the substrate, the second central separator is arranged between the second main opening and the second sub-opening.

12. The display apparatus of claim 11, wherein the first central separator and the second central separator are integrally formed with each other as a single unitary indivisible part.

13. The display apparatus of claim 11, wherein the first central separator and the second central separator are arranged to be apart from each other.

14. The display apparatus of claim 10, further comprising:
a first outer separator surrounding at least a portion of an outer portion of a first sub-pixel group including the first main light-emitting diode and the first sub light-emitting diode when viewed in the direction perpendicular to the substrate; and
a second outer separator surrounding at least a portion of an outer portion of a second sub-pixel group including the second main light-emitting diode and the second sub light-emitting diode when viewed in the direction perpendicular to the substrate.

15. The display apparatus of claim 14, wherein, when viewed in the direction perpendicular to the substrate, the first outer separator and the second outer separator are arranged to be apart from each other between the first sub-pixel group and the second sub-pixel group.

16. The display apparatus of claim 1, further comprising:
an encapsulation layer disposed on the first main light-emitting diode and the first sub light-emitting diode; and
a light-blocking layer disposed on the encapsulation layer,
wherein, when viewed in the direction perpendicular to the substrate, the light-blocking layer defines a plurality of light-transmissive openings respectively overlapping the first main opening and the first sub-opening of the bank layer.

17. The display apparatus of claim 16, wherein the light-blocking layer includes a first light-blocking line and a second light-blocking line extending in directions crossing each other,
wherein the first light-blocking line overlaps each of the first main light-emitting diode and the first sub light-emitting diode when viewed in the direction perpendicular to the substrate, and
the second light-blocking line is arranged to be adjacent to an opposite lateral surface of a lateral surface facing the first main light-emitting diode among lateral surfaces of the first sub light-emitting diode when viewed in the direction perpendicular to the substrate.

18. The display apparatus of claim 1, wherein the first main light-emitting diode and the first sub light-emitting diode respectively emit light according to different electrical signals from each other.

19. The display apparatus of claim 1, wherein, when viewed in the direction perpendicular to the substrate, an emission area of the first main light-emitting diode is greater than an emission area of the first sub light-emitting diode.

20. A display apparatus comprising:
a substrate;
a sub-pixel group disposed on the substrate and including a main light-emitting diode and a sub light-emitting diode, which emit light of a same color as each other and are disposed to be adjacent to each other;
a bank layer defining a main opening exposing the main light-emitting diode, and a sub opening exposing the sub light-emitting diode; and
a separator disposed on an upper surface of the bank layer,
wherein, the separator includes:
an outer separator surrounding at least a portion of an outer portion of the sub-pixel group when viewed in a direction perpendicular to the substrate; and
a central separator disposed between the main light-emitting diode and the sub light-emitting diode when viewed in the direction perpendicular to the substrate.

21. The display apparatus of claim 20, wherein the separator is defined by a trench shape of the bank layer in which a portion of the upper surface of the bank layer is concave.

22. The display apparatus of claim 20, wherein the separator is defined by a structure disposed on the upper surface of the bank layer, and a lateral surface of the separator includes a reverse tapered inclined surface.

23. The display apparatus of claim 20, wherein the main light-emitting diode includes a main pixel electrode, a main intermediate layer on the main pixel electrode, and a main opposite electrode on the main intermediate layer,
the sub light-emitting diode includes a sub-pixel electrode, a sub-intermediate layer on the sub-pixel electrode, and a sub-opposite electrode on the sub-intermediate layer,
the main intermediate layer and the sub-intermediate layer are apart from each other with the central separator therebetween, and
the main opposite electrode and the sub-opposite electrode are apart from each other with the central separator therebetween.

24. The display apparatus of claim 20, wherein the main light-emitting diode and the sub light-emitting diode respectively emit light based on different electrical signals from each other.

25. An electronic apparatus comprising a display apparatus,
Wherein the display apparatus comprises:
a substrate;
a first main light-emitting diode disposed on the substrate;
a first sub light-emitting diode disposed on the substrate to be adjacent to the first main light-emitting diode, wherein the first sub light-emitting diode emits light of a same color as the first main light-emitting diode;
a bank layer defining a first main opening exposing the first main light-emitting diode and a first sub-opening exposing the first sub light-emitting diode; and
a first central separator disposed on an upper surface of the bank layer, wherein when viewed in a direction perpendicular to the substrate, the first central separator is arranged between the first main opening and the first sub-opening.

26. The electronic apparatus of claim 25, further comprising:
a display module;
a processor;
a power module; and
a memory,
wherein the display apparatus includes one of the display module, the processor, the power module, or the memory.
